(19) United States
(12) Patent Application Publication
(10) Pub. No.: US 2011/0297425 A1
(43) Pub. Date: Dec. 8, 2011

(54) WIRING SUBSTRATE AND MANUFACTURING METHOD THEREOF

(75) Inventors: Junichi Nakamura, Nagano (JP); Hitoshi Kondo, Nagano (JP); Tomoyuki Shimodaira, Nagano (JP); Katsutoshi Tanabe, Nagano (JP)

(73) Assignee: SHINKO ELECTRIC INDUSTRIES CO., LTD., Nagano (JP)

(21) Appl. No.: 13/094,546

(22) Filed: Apr. 26, 2011

(30) Foreign Application Priority Data
Jun. 4, 2010 (JP) 2010-128983

(51) Int. Cl. H05K 1/02; H05K 3/02

(52) U.S. Cl. 174/251; 29/847

(57) ABSTRACT

A wiring substrate includes a plurality of insulating layers; and a plurality of wiring layers being alternately laminated, wherein an opening portion is formed in an outermost insulating layer to expose a part of the outermost wiring layer to an outside, a cross-sectional shape of a sidewall of the opening portion is concaved and curved, and the outermost wiring layer has a recess on a side exposed to the outside.

### CROSS-REFERENCE TO RELATED APPLICATIONS

This patent application is based upon and claims the benefit of priority of the prior Japanese Patent Application No. 2010-128983 filed on Jun. 4, 2010, the entire contents of which are incorporated herein by reference.

### FIELD

A certain aspect of the embodiments discussed herein is related to a wiring substrate in which an insulating layer for covering a wiring layer has an opening portion from which a part of the wiring layer is exposed to the outside, and a manufacturing method of the wiring substrate.

### BACKGROUND

Japanese Laid-open Patent Publication No. 2008-140886 discloses a technique in which a wiring substrate is manufactured by a method, wherein an insulating resin layer for covering an uppermost wiring layer, including wiring having a part thicker than the other part, is formed, and a part of this insulating resin layer is removed, until an upper part of a part whose thickness is large in the uppermost wiring layer is removed, and the same becomes exposed.

Japanese Laid-open Patent Publication No. 2000-286362 discloses a technique in which a circuit board is formed using a double-sided printed wiring board of thickness 0.04 to 0.15 mm as a substrate of a semiconductor plastic package, and a prepreg of a glass cloth-based thermosetting resin composition of the same thickness is laminated on each side of the circuit board. Bonding pads and ball pads are removed through a sand blasting method, and the circuit board is plated with precious metal to serve as a printed wiring board.

### SUMMARY

According to an aspect of the embodiment, a wiring substrate includes a plurality of insulating layers; and a plurality of wiring layers being alternately laminated, wherein an opening portion is formed in an outermost insulating layer to expose a part of the outermost wiring layer to an outside, a cross-sectional shape of a sidewall of the opening portion is concaved and curved, and the outermost wiring layer has a recess on a side exposed to the outside.

The object and advantages of the invention will be realized and attained by means of the elements and combinations particularly pointed out in the appended claims.

It is to be understood that both the foregoing general description and the following detailed description are exemplary and explanatory and are not restrictive of the invention, as claimed.

### BRIEF DESCRIPTION OF THE DRAWINGS

FIG. 1 is a cross-sectional view of an example wiring substrate;

FIG. 2 is a cross-sectional view schematically illustrating a state in which a pin is inserted into an opening portion;

FIG. 3 is a cross-sectional view of an example wiring substrate of Embodiment 1;

FIG. 4 is an enlarged cross-sectional view illustrating opening portion (recess) of FIG. 13 and portions in the vicinity of the opening portion;

FIG. 5 is an enlarged cross-sectional view illustrating the opening portion (recess) formed by a laser processing method and portions in the vicinity of the opening portion;

FIG. 6 illustrates a first step of an example manufacturing process of the wiring substrate of Embodiment 1;

FIG. 7 illustrates a second step of the example manufacturing process of the wiring substrate of Embodiment 1;

FIG. 8 illustrates a third step of the example manufacturing process of the wiring substrate of Embodiment 1;

FIG. 9 illustrates a fourth step of the example manufacturing process of the wiring substrate of Embodiment 1;

FIG. 10 illustrates a fifth step of the example manufacturing process of the wiring substrate of Embodiment 1;

FIG. 11 illustrates a sixth step of the example manufacturing process of the wiring substrate of Embodiment 1;

FIG. 12 illustrates a seventh step of the example manufacturing process of the wiring substrate of Embodiment 1;

FIG. 13 illustrates an eighth step of the example manufacturing process of the wiring substrate of Embodiment 1;

FIG. 14 illustrates a ninth step of the example manufacturing process of the wiring substrate of Embodiment 1;

FIG. 15 is a cross-sectional view of a wiring substrate of Modified example 1 of Embodiment 1;

FIG. 16 is an enlarged cross-sectional view of an opening portion and portions in the vicinity of the opening portion of a wiring substrate of Modified example 2 of Embodiment 1;

FIG. 17 is a cross-sectional view of the opening portion of the wiring substrate and the portions in the vicinity of the opening portion of Modified example 2 of Embodiment 1;

FIG. 18 is a plan view of opening portions in a wiring substrate and portions in the vicinity of the opening portions of Modified example 3 of Embodiment 1;

FIG. 19 is a cross-sectional view of the wiring substrate of Modified example 3 of Embodiment 1;

FIG. 20 is a cross-sectional view of an example wiring substrate of Embodiment 2;

FIG. 21 is a cross-sectional view illustrating the opening portions (recesses) of FIG. 20 and portions in the vicinity of the opening portions;

FIG. 22 is a cross-sectional view of example glass cloth.

FIG. 23 is an enlarged cross-sectional view illustrating opening portions (recesses) of glass cloth formed by a laser processing method and the portions in the vicinity of the opening portions;

FIG. 24 is a cross-sectional view of a semiconductor package of Embodiment 3;

FIG. 25 is a cross-sectional view of a semiconductor package of Embodiment 4;

FIG. 26 is an electron microscope photograph of the opening portion and the portion in the vicinity thereof of the wiring substrate of Embodiment 1 captured by a scanning electron microscope (SEM); and

FIG. 27 is an electron microscope photograph of the opening portion and the portion in the vicinity thereof of the wiring substrate of comparative example 1 captured by a scanning electron microscope (SEM).

### DESCRIPTION OF EMBODIMENTS

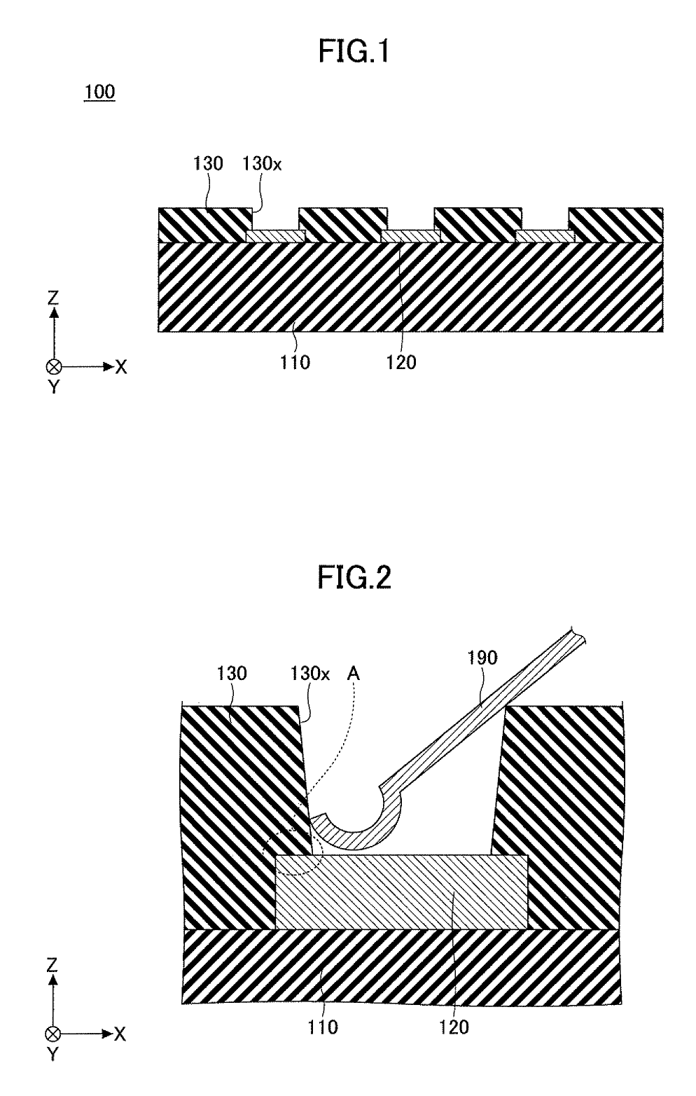

FIG. 1 is a cross-sectional view of an example wiring substrate. Referring to FIG. 1 and FIG. 2, an example wiring substrate 100 has a structure in which a first insulating layer 110, a wiring layer 120 and a second insulating layer 130 are sequentially laminated.

The first insulating layer 110 is a layer for forming the wiring layer 120 and formed of a nonphotosensitive insulating resin or the like. The wiring layer 120 is formed of copper (Cu) or the like. The second insulating layer 130 is formed on the first insulating layer 110 to cover the wiring layer 120. The second insulating layer 130 has an opening portion 130x, and a part of the wiring layer 120 is exposed inside the opening portion 130x. The second insulating layer 130 is ordinarily made of a photosensitive resin and the opening portion 130x is ordinarily formed by a photolithography method.

There is a case where a wiring layer and an insulating layer are further laminated below the first insulating layer 110. Only the second insulating layer 130 of the uppermost layer is ordinarily made of a photosensitive insulating resin, and an insulating layer (including the first insulating layer) other than the second insulating layer 130 on the uppermost layer may ordinarily be made of a nonphotosensitive insulating resin.

FIG. 2 is a cross-sectional view schematically illustrating a state in which a pin is inserted into an opening portion. Referring to FIG. 2, a pin 190 of a socket is inserted into an opening portion 130x in which a wiring layer 120 is exposed to the outside as a land of a so-called Land Grid Array (LGA). Referring to FIG. 2, a cross-section of aside wall of the opening portion 130x formed by a photolithographic method has a linear shape substantially orthogonal to an upper surface of the wiring layer 120. Therefore, it is difficult to insert the pin 190 into the opening portion 130x, and the pin 190 scarcely reaches the wiring layer 120 exposed to the inside of the opening portion 130x. With this, there are problems that the pin 190 is not sufficiently inserted into the opening portion 130x and does not contact the wiring layer 120.

Further, there is a problem in which the wiring layer 120 does not contact the second insulating layer 130 well and an interface A is torn away by a force applied to the interface A between the wiring layer 120 and the second insulating layer 130.

As described, when the opening portion is formed by the photolithographic method, there may occur the insertion failure of the pin into the opening portion, the contact failure of the pin, a contact failure between the wiring layer in the vicinity of the opening portion and the insulating layer covering the wiring layer, and the like. In these cases, connection reliability between the wiring board (mounting board) and the pins may be degraded.

Preferred embodiments of the present invention will be explained with reference to accompanying drawings.

### Embodiment 1

Embodiment 1 describes an application to a wiring substrate which becomes a semiconductor package by mounting a semiconductor chip.

### [Structure of the Wiring Substrate of Embodiment 1]

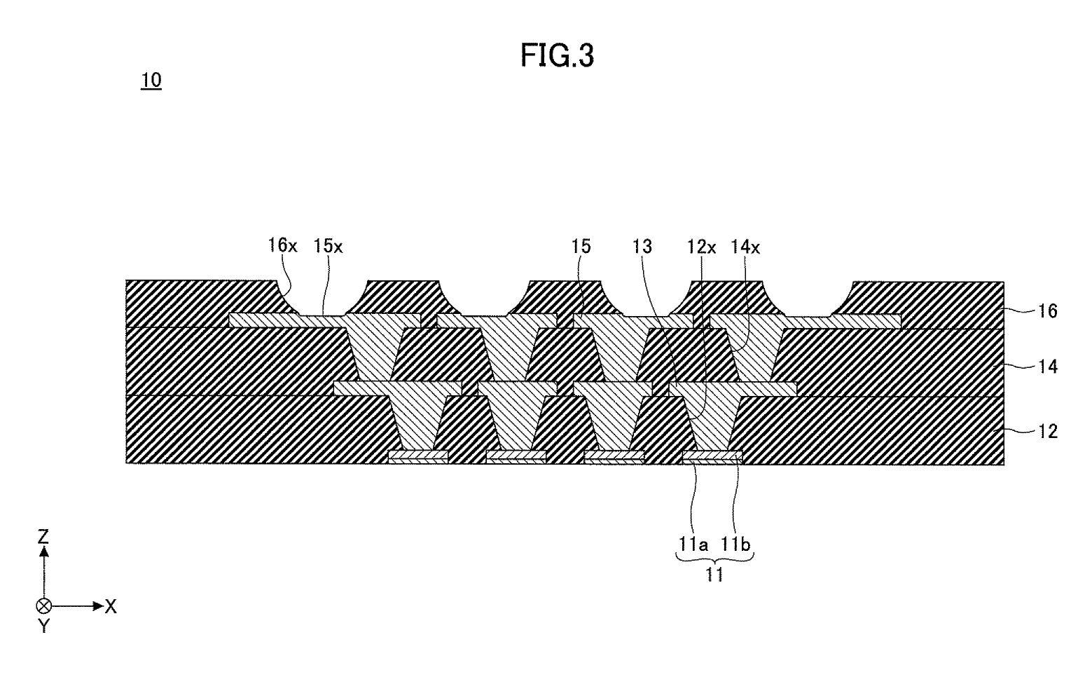

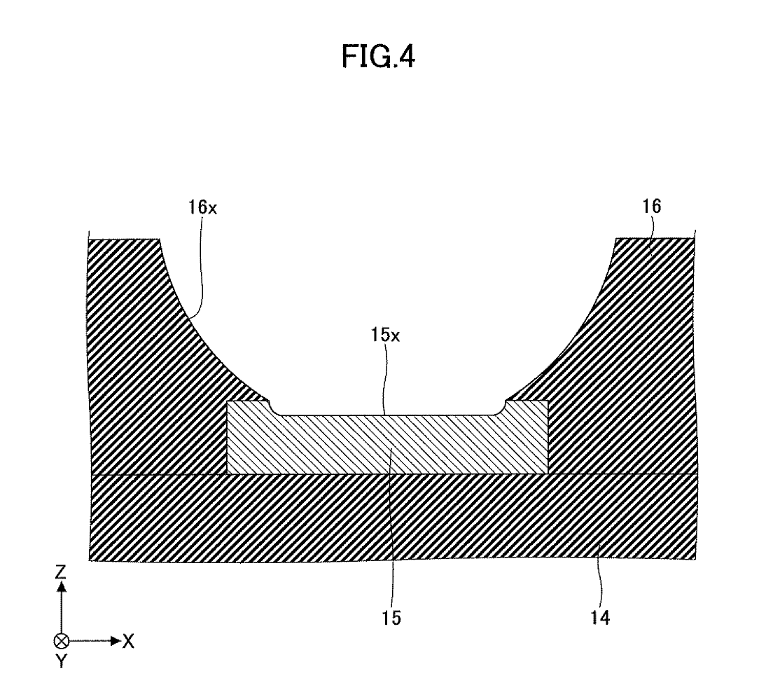

First, the structure of a wiring substrate of Embodiment 1 is described. FIG. 3 is a cross-sectional view of an example wiring substrate of Embodiment 1. Referring to FIG. 3, the wiring substrate 10 of Embodiment 1 has a structure in which a first wiring layer 11, a first insulating layer 12, a second wiring layer 13, a second insulating layer 14, a third wiring layer 15 and a third insulating layer 16 are sequentially laminated.

The first wiring layer 11 is the lower-most layer of the wiring substrate 10. The first wiring layer 11 includes a first layer 11a and a second layer 11b. The first layer 11a may be a conductive layer formed by sequentially laminating a gold (Au) film, a palladium (Pd) film and a nickel (Ni) film in this order while the gold (Au) layer is exposed to the outside. The second layer 11b is a conductive layer including copper (Cu) or the like.

The first layer 11a being a part of the first wiring layer 11 is exposed from the first insulating layer 12 and functions as electrode pads connected to a semiconductor chip (not illustrated) or the like. A plan view of a part of the first wiring layer 11 exposed from the first insulating layer 12 may be in a circular shape, and the diameter of the circular shape may be about 40 through 120 μm. The pitch of the parts of the first wiring layer 11 exposed from the first insulating layer 12 may be about 100 through 200 μm. The thickness of the first wiring layer 11 may be about 10 to 20 μm.

The first insulating layer 12 covers upper surfaces (faces connected to via wirings of the second wiring layer 13) and side surfaces of the first wiring layer 11. Lower surfaces (surfaces opposite to a surface connected to the via wirings) of the first wiring layer 11 are exposed to the outside. The material of the first insulating layer 12 may be a nonphotosensitive insulating resin mainly containing an epoxy resin. The nonphotosensitive insulating resin may be a thermoset resin. The thickness of the first insulating layer 12 may be about 15 through 35 μm.

The first insulating layer 12 contains a filler such as silica (SiO₂). A contained amount of the filler may be about 20 through 70 vol %. Preferably, the minimum particle diameter of the filler is 0.1 μm, the maximum particle diameter of the filler is 5.0 μm, and the average particle diameter of the filler is 0.5 through 2.0 μm. By adjusting the contained amount of the filler, it is possible to adjust a thermal expansion coefficient of the first insulating layer 12. For example, by increasing the contained amount of the filler, the thermal expansion coefficient can be decreased. It is possible to reduce warpage of the wiring substrate 10 by bringing the thermal expansion coefficient of the first insulating layer 12 near to the thermal expansion coefficient (about 17 ppm/° C.) of copper (Cu), of which the second wiring layer 13 or the like is made, by adjusting the contained amount of the filler. Except for a specifically described case, the thermal expansion coefficient described in the specification is for a range of 25 through 150° C.

The second wiring layer 13 is formed on the first insulating layer 12. The second wiring layer 13 includes via wirings which penetrate through the first insulating layer 12 and are supplied inside first via holes 12x, from which the upper surfaces of the parts of the first wiring layer 11 are exposed, and wiring patterns formed on the first insulating layer 12. The second wiring layer 13 is electrically connected to the first wiring layer 11 exposed toward the inside of the first wiring layer 11. The material of the second wiring layer 13 maybe copper (Cu) or the like. The thicknesses of the wiring patterns of the second wiring layers 13 may be about 10 to 20 μm.

The second insulating layer 14 is formed to cover the second wiring layer 13 on the first insulating layer 12. The material of the second insulating layer 14 is preferably a nonphotosensitive insulating resin having the same structure as the first insulating layer 12. The second insulating layer 14 preferably contains a filler having the same composition as the filler contained in the first insulating layer 12 of substantially the same amount. This is to reduce the warpage caused in the wiring substrate 10. The thickness of the first insulating layer 14 may be about 15 through 35 μm.

The third wiring layer 15 is provided as the uppermost wiring layer or the outermost wiring layer which is formed on the second insulating layer 14. The third wiring layer 15 includes via wirings which penetrate through the second insulating layer 14 and are supplied inside second via holes 14x, from which the upper surfaces of the second wiring layers 13 are exposed, and wiring patterns formed on the second insulating layer 14. The third wiring layer 15 is electrically connected to the second wiring layer 13 exposed toward the second via holes 14x. The material of the third wiring layer 15 may be copper (Cu) or the like. The thicknesses of the third wiring layers 15 may be about 10 to 20 μm.

The third insulating layer 16 is the uppermost insulating layer or the outermost insulating layer which is formed to cover the third wiring layer 15 on the second insulating layer 14. The material of the third insulating layer 16 is a nonphotosensitive insulating resin having the same composition as the first insulating layer 12 and the second insulating layer 14. The third insulating layer 16 preferably contains a filler having the same composition as the filler contained in the first insulating layer 12 and the second insulating layer 14 of substantially the same amount. This is to reduce the warpage caused in the wiring substrate 10. The thickness of the third insulating layer 16 may be about 15 through 35 μm.

The third insulating layer 16 includes opening portions 16x, and recesses 15x of the third wiring layer 15 are exposed to bottom portions of the opening portions 16x. The recesses 15x function as electrode pads electrically connected to amounting board (not illustrated) such as a motherboard. When necessary, metallic layers or the like may be formed on the recesses 15x. An example of the metallic layer is an Au layer, a Ni/Au layer which is a metallic layer formed by laminating a Ni layer and an Au layer in this order, a Ni/Pd/Au layer which is a metallic layer formed by laminating a Ni layer, a Pd layer, and an Au layer in this order or the like.

When the metallic layers or the like are formed on the recesses 15x, it is possible to further form external connection terminals such as solder balls and lead pins on the metallic layer. However, the external connection terminals may be formed when necessary.

The via holes 12x and 14x formed in the insulating layers 12 and 14 are opened toward the third insulating layer 16 (the uppermost insulating layer). The bottom surfaces of the via holes 12x and 14x are formed by the surfaces of the other wiring layers 11 and 13. Thus, the areas of the opening portions become greater than the areas of the bottom surfaces to thereby form the recesses in the shape of a circular truncated cone. The respective via wirings are formed inside the recesses.

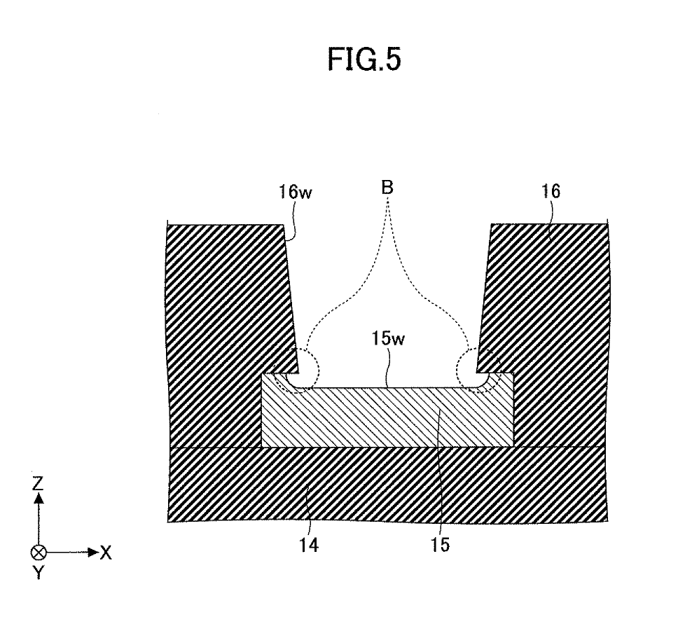

FIG. 4 is an enlarged cross-sectional view illustrating the opening portion 16x of FIG. 3 and portions in the vicinity of the opening portion. Referring to FIG. 4, the opening portions 16x are broadened toward opening ends of the opening portions 16x, and cross-sectional views of sidewalls are in concaved and curved shapes. The opening portions 16x may be formed like hemispheres. The opening portions 16x are in circular shapes in their plan views, and diameters of the opening portions of the opening portions 16x may be about 220 through 1100 μm. The opening portion is formed to be broadened from the outermost wiring layer to an upper surface of the outermost insulating layer.

The recesses 15x are broadened from the bottom surfaces toward opening ends of the recesses 15x, and cross-sectional views of sidewalls are in concaved and curved shapes. The outer edge portion of the recess 15x does not intrude into a lower portion of the third insulating layer 16. The outermost edge portion of the sidewall of the recess 15x is continuously formed from the innermost edge portion of the sidewall of the opening portion 16x. The plan view of the recess 15x may be like a circle having a diameter of about 200 through 1000 μm. The pitches of the recesses 15x may be about 500 through 1200 μm. The depth of the recesses 15x based on the upper surface of the third wiring layer 15 may be about 0.5 through 4 μm.

The cross-sectional shape of the sidewall of the opening portion 16x is in the concaved and curved shape as described above because the opening portion 16x is formed by a blasting process. When the opening portion 16x is formed, the upper surface of the third wiring layer 15 is subsequently abraded by the blasting process. Thus, the recess 15x is continuously formed from the opening portion 16x.

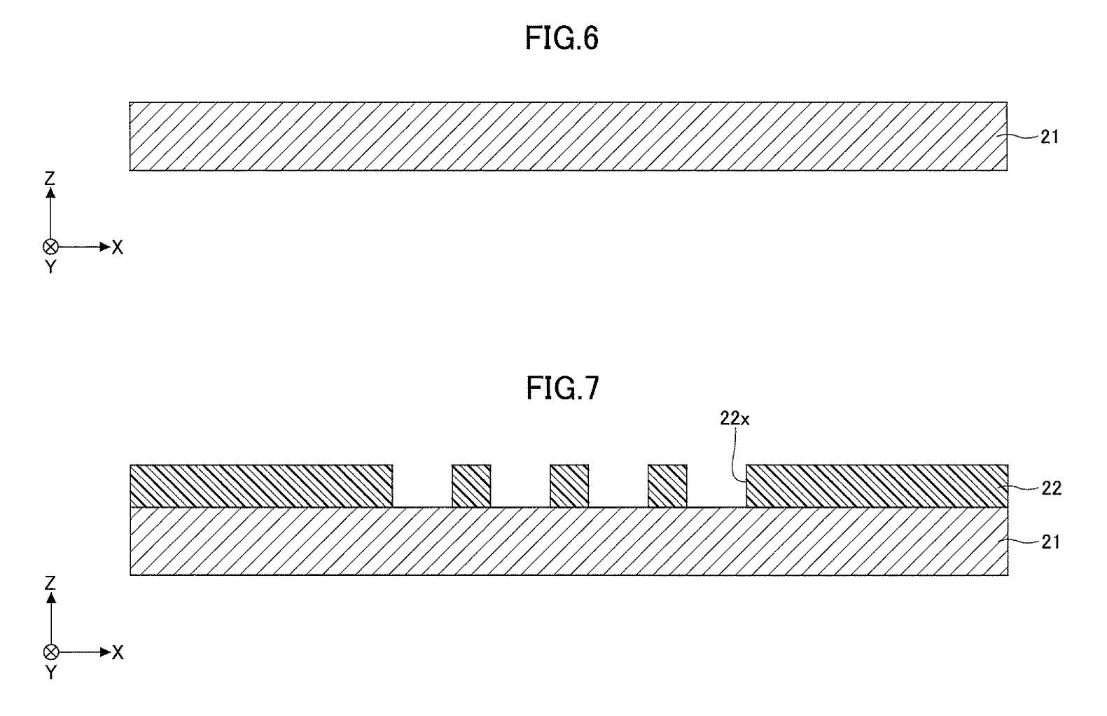

Although a laser processing method may be used to form the opening portion, it is not preferable. Hereinafter, the reason is explained. FIG. 5 is an enlarged cross-sectional view illustrating the opening portion (recess) formed by a laser processing method and portions in the vicinity of the opening portions. Referring to FIG. 5, the cross-sectional view of the sidewall of the opening portion 16w is linear and provided substantially perpendicular to the upper surface of the third wiring layer 15. A recess 15w is formed at a portion exposing inside the opening portion 16w of the third wiring layer 15. An outer edge portion of the recess 15w intrudes into a lower portion of the third insulating layer 16 unlike the recess 15x illustrated in FIG. 4 like a portion of a region B illustrated in FIG. 5. Regions B are so-called hollowing regions. There is contact failure in an interface between the third wiring layer 15 and the third insulating layer 16.

The hollowing is caused by the following process. Said differently, when the opening portion 16w is formed by the laser processing method, residue of a material of the third insulating layer 16 is left on the surface of the third wiring layer 15 exposed toward the inside of the opening portion 16w. In order to remove the residue, a desmear process may be provided. However, an etching solution used for the desmear process dissolves a part of the third wiring layer 15 to thereby form the recess 15w. The etching solution penetrates into an interface between the third wiring layer 15 and the third insulating layer 16 in regions B. Then, the third wiring layer 15 under the third insulating layer 16 is dissolved to thereby cause hollowing.

When the hollowing is caused, contact failure occurs between the third wiring layer 15 and the third insulating layer 16 in the regions B. Then, the interface between the third wiring layer 15 and the third insulating layer 16 may be peeled away. If the interface is peeled away, connection reliability in connecting the wiring substrate 10 to the mounting board, electronic parts or the like may be degraded.

With Embodiment 1, the opening portion 16x is formed by the blast process. In the blast process, the hollowing is not caused since an etching solution used in the desmear process is not used. Since the opening portion 16x and the recess 15x are continuously formed by the blast process, the outer edge portion of the recess 15x does not intrude under the third insulating layer 16 and the outermost edge portion of the sidewall of the recess 15x is continuously formed from the innermost edge portion of the sidewall of the opening portion 16x of the recess 15x. Said differently, the outermost edge portion of the sidewall of the recess 15x is continuously curved from the innermost edge portion of the sidewall of the opening portion 16x in their cross-sectional shapes. An effect of the above-described shapes of the opening portion 16x and the recess 15x is described next.

In comparison with FIG. 2, FIG. 4 and FIG. 5, when the areas of the wiring layers exposed inside the opening portions are the same, effective areas of the opening portions accessible through the upper surfaces of the insulating layers (opening ends) become greater in the opening portion 16x in which the sidewall has the cross-sectional concaved and curved shape than in the opening portions 130x and 16w in which the sidewalls have the linear shape. Therefore, it is easier to insert a pin for a LGA socket into the opening portion 16x than into the opening portion 130x and the opening portion 16w. Thus, it is possible to reduce occurrences of insertion failure of the pins and contact failure of the pins.

In the opening portion 16x, the hollowing illustrated in FIG. 5 is not caused in the interface between the third wiring layer 15 and the third insulating layer 16. Therefore, it is possible to prevent the contact failure between the third wiring layer 15 and the third insulating layer 16.

The bottom surface of the recess 15x is not in the same plane as that of the interface. The bottom surface of the recess 15x is positioned lower than the interface between the third wiring layer 15 and the third insulating layer 16. Therefore, it is possible to reduce peeling-off of the interface by preventing a direct force from being applied to the interface between the third wiring layer 15 and the third insulating layer 16 from the pin for LGA socket.

The bottom surface of the recess 15w is not in the same plane as that of the interface. The bottom surface of the recess 15w is positioned lower than the interface between the third wiring layer 15 and the third insulating layer 16. Since the contact failure caused by the hollowing is caused in FIG. 5, it is not possible to reduce the peeling-off of the interface in the recess 15w.

With Embodiment 1, the cross-sectional shape of the sidewall of the opening portion is concaved and curved, and the recesses are formed on the wiring layer at a portion exposed to the opening portion of the insulating layer. Therefore, the insertion failure and contact failure of the pin inserted into the opening portion and the contact failure between the wiring layer and the insulating layer covering the wiring layer are not easily caused. As a result, it is possible to improve connection reliability at a time of connecting the wiring substrate to the mounting board, the electronic parts or the like.

### [Manufacturing Method of the Wiring Substrate of Embodiment 1]

Next, the manufacturing method of the wiring substrate of Embodiment 1 is described. FIG. 6 to FIG. 14 illustrate example manufacturing steps of the wiring substrate of Embodiment 1.

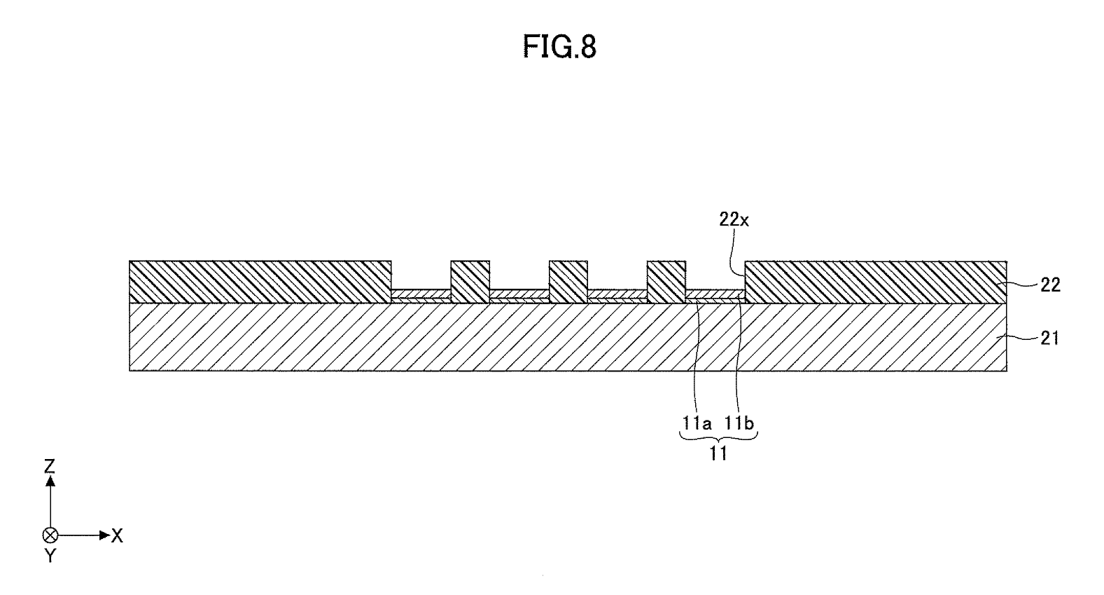

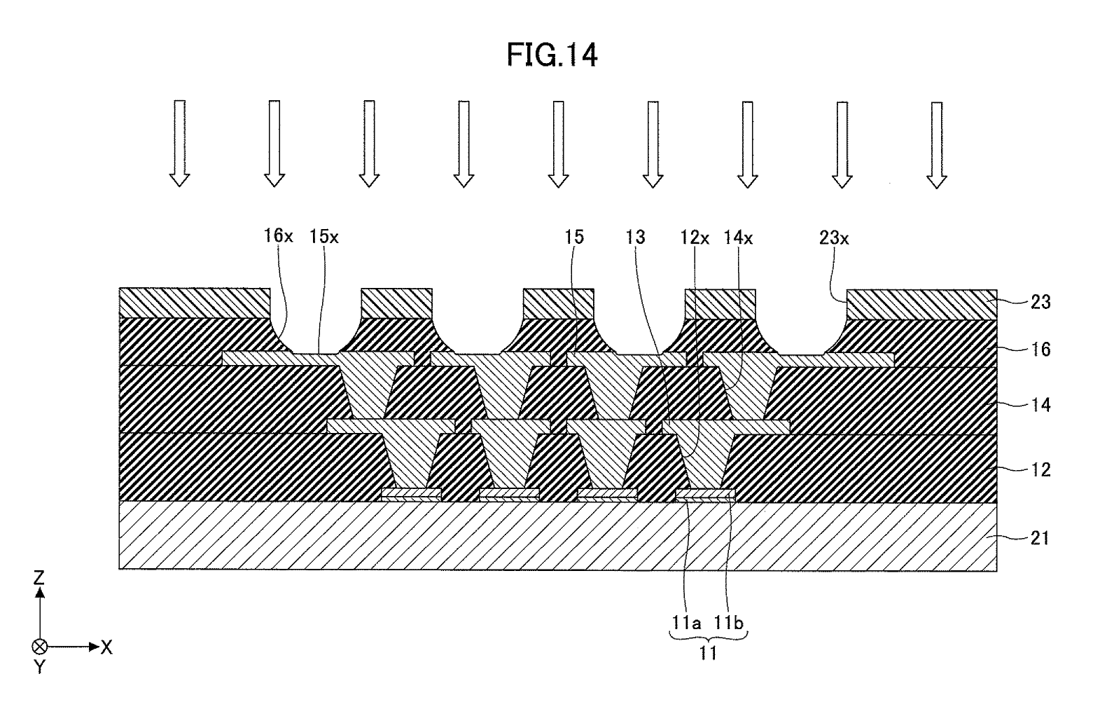

Referring to FIG. 6, a supporting body 21 is prepared. The supporting body 21 is a silicon plate, a glass plate, a metallic plate, a metallic foil, or the like. A copper foil is used as the supporting body 21 in Embodiment 1. This is because the supporting body 21 is used as a power supply layer for electro plating in the step illustrated in FIG. 8 described below. The supporting body 21 can be easily removed after the step illustrated in FIG. 14 described below. The thickness of the supporting body 21 may be about 35 to 100 μm.

In the step illustrated in FIG. 7, a resist layer 22 having opening portions 22x corresponding to the first wiring layer 11 is formed on a surface of the supporting body 21. Specifically, a liquid or paste resist made of a photosensitive resin composition containing an epoxy resin, an imide resin or the like is coated on the surface of the supporting body 21. Alternatively, a film resist such as a dry film resist made of a photosensitive composition containing an epoxy resin, an imide resin or the like is laminated on the surface of the supporting body 21. By irradiating the coated or laminated resist with light and developing the coated or laminated resist, the opening portions 22x are formed. With this, the resist layer 22 having the opening portions 22x is formed. It is possible to laminate a film resist previously having the opening portions 22x on the surface of the supporting body 21.

The opening portions 22x are formed at positions corresponding to the first wiring layer 11 formed in a step to be illustrated in FIG. 8. However, a pitch of arranging the opening portions 22x may be about 100 through 200 μm. The opening portion 22x is in a circular shape in its plan view, and a diameter of the opening portion 22x may be about 40 through 120 μm.

In the step illustrated in FIG. 8, the first wiring layer 11 including a first layer 11a and a second layer 11b is formed inside the opening portions 22x on the surface of the supporting body 21 by electro plating or the like using the supporting body 21 as the power supply layer.

The first layer 11a has a structure formed by sequentially laminating a gold (Au) film, a palladium (Pd) film and a nickel (Ni) film in this order. In order to form the first wiring layer 11, first layer 11a is formed by sequentially plating the gold (Au) film, the palladium (Pd) film and the nickel (Ni) film in this order by electro plating or the like using the supporting body 21 as the power supply layer, and then the second layer 11b made of copper (Cu) or the like is formed on the first layer 11a by an electro plating using the supporting body 21 as the power supply layer.

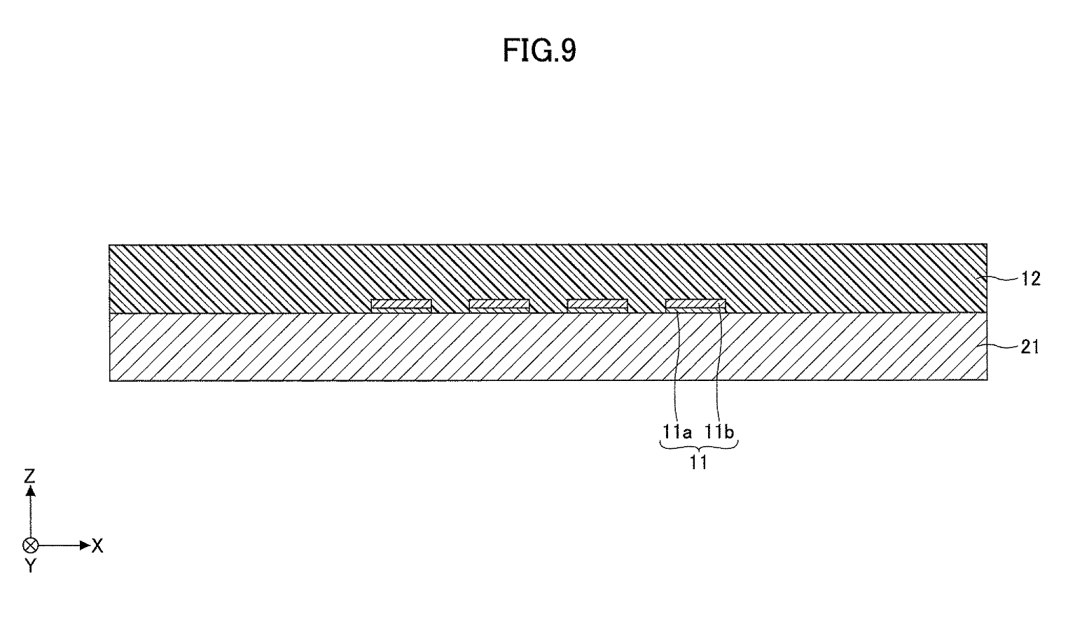

Referring to FIG. 9, after removing the resist layer 22 illustrated in FIG. 8, the first insulating layer 12 is formed on the surface of the supporting body 21 so as to cover the first wiring layer 11. The material of the first insulating layer 12 may be a nonphotosensitive insulating resin mainly containing an epoxy resin. The thickness of the first insulating layer 12 may be about 15 through 35 μm. The first insulating layer 12 contains a filler such as silica (SiO₂). The purpose of the filler and its contained amount are as follows.

When the nonphotosensitive insulating resin whose main component is a film-like thermoset epoxy resin is used as the material of the first insulating layer 12, the film-like first insulating layer 12 may be laminated on the surface of the supporting body 21 so as to cover the first wiring layer 11. After pressing the laminated first insulating layer 12, the first insulating layer 12 is heated at the curing temperature or more and cured or hardened. It is possible to prevent voids from being formed by laminating the first insulating layer 12 under a vacuum atmosphere.

When the nonphotosensitive insulating resin whose main component is a liquid-like or paste-like thermoset epoxy resin is used as the material of the first insulating layer 12, the liquid-like or paste-like first insulating layer 12 may be coated on the surface of the supporting body 21 so as to cover the first wiring layer 11. The coated first insulating layer 12 is heated at the curing temperature or more to harden the first insulating layer 12.

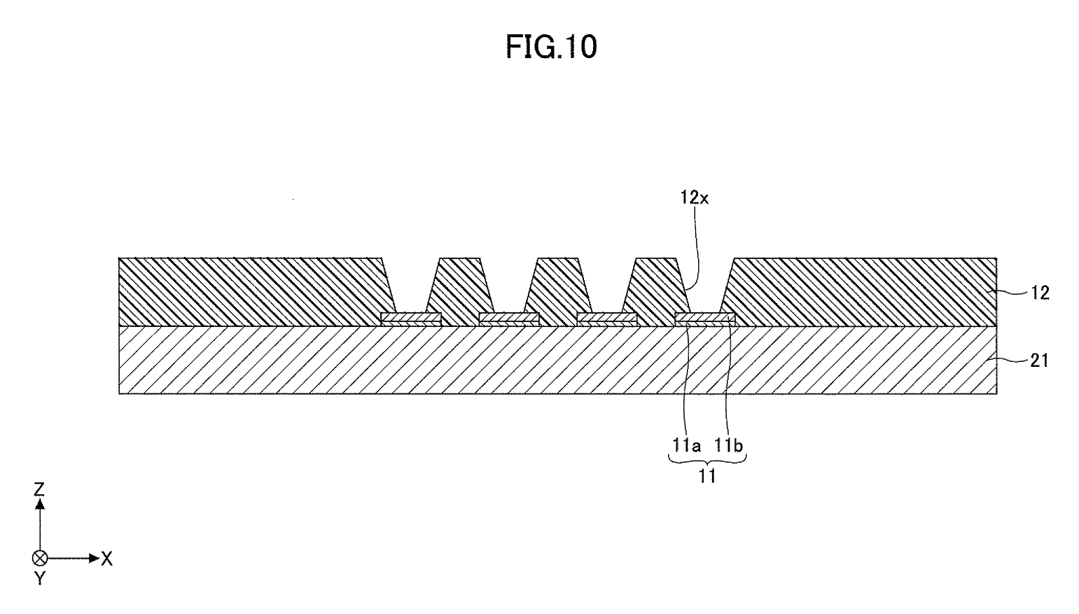

Referring to FIG. 10, first via holes 12x which penetrate the first insulating layer 12 and from which the face of the first wiring layer 11 is exposed are formed. The first via holes 12x may be formed by a laser processing method using, for example, a CO₂ laser. When the first via holes 12x are formed by the laser processing method, a desmear process is carried out to remove resin residue of the first insulating layer 12 adhered to the upper surface of the first wiring layer 11 which is exposed toward the inside of the first via holes 12x.

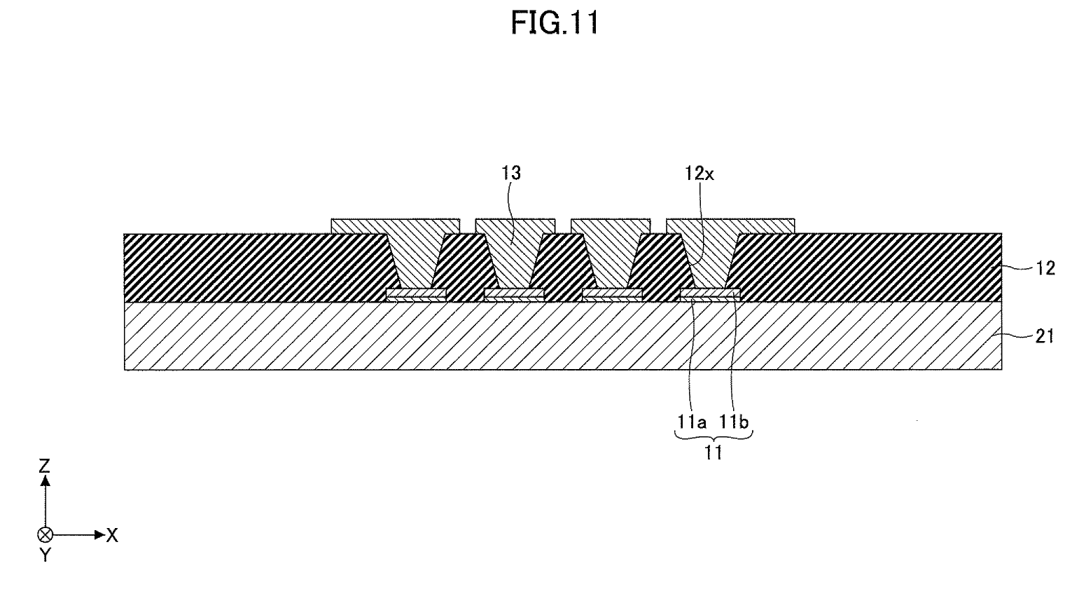

Referring to FIG. 11, the secondwiring layer 13 is formed on the first insulating layer 12. The second wiring layer 13 includes via wirings supplied inside the first via holes 12x and a wiring pattern formed on the first insulating layer 12. The second wiring layer 13 is electrically connected to the first wiring layer 11 exposed toward the first via holes 12x. The material of the second wiring layer 13 may be copper (Cu) or the like.

The second wiring layer 13 maybe formed by various wiring forming methods such as a semi-additive method and a subtractive method. As an example, a method of forming the second wiring layers 13 using the semi-additive method is described next.

First, a seed layer (not illustrated) made of copper (Cu) or the like is formed on the upper surface of the first wiring layer 11 exposed inside the first via holes 12x and on the first insulating layer 12 including the sidewalls of the first via holes 12x by an electroless plating or a sputtering method. Further, a resist layer (not illustrated) having the opening portions corresponding to the second wiring layer 13 is formed on the seed layer. A wiring layer (not illustrated) made of copper (Cu) is formed on the opening portions of the resist layer by the electro plating in which the seed layer is used as the power supplying layer. Subsequently, after removing the resist layer, a portion of the seed layer which is not covered by the wiring layer is removed by etching using the wiring layer as a mask. With this, the second wiring layer 13 includes the via wirings supplied inside the first via holes 12x in the first insulating layer 12 and the wiring pattern formed on the first insulating layer 12.

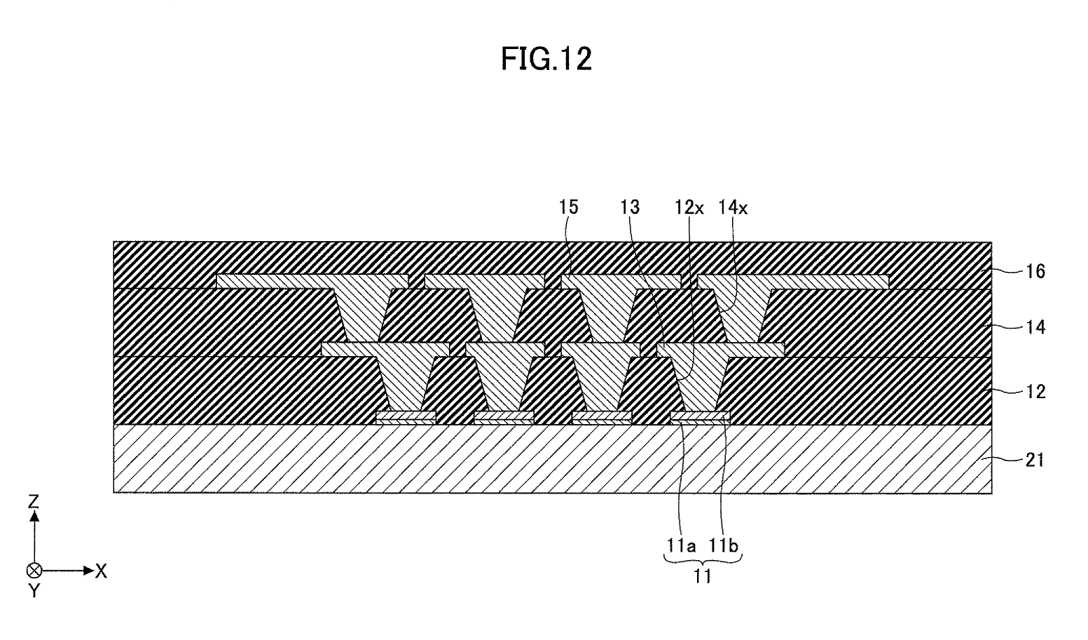

Referring to FIG. 12, by repeating the above processes, the second insulating layer 14, the third wiring layer 15 and the third insulating layer 16 are laminated on the first insulating layer 12. Said differently, after forming the second insulating layer 14 covering the second wiring layer 13 on the first insulating layer 12, the second via holes 14x are formed in the second insulating layer 14 provided on the second wiring layer 13.

Further, the third wiring layer 15 to be connected to the second wiring layer 13 is formed on the second insulating layer 14 via the second via holes 14x. The material of the third wiring layer 15 may be copper (Cu) or the like. The third wiring layer 15 may be formed by the semi-additive method.

Further, the third insulating layer 16 covering the third wiring layer 15 is formed on the second insulating layer 14. The material of the second and third insulating layers 14 and 16 is a nonphotosensitive insulating resin having the same composition as that of the first insulating layer 12. The second and third insulating layers 14 and 16 preferably contain a filler having the same composition of substantially the same amount as that of the filler contained in the first insulating layer 12. This is to reduce warpage caused in the wiring substrate 10. The thicknesses of the second and third insulating layers 14 and 16 may be about 15 through 35 μm.

As described, a predetermined buildup wiring layer is formed on the one surface of the supporting body 21. With this Embodiment, the two-layer built-up wiring layer including the second wiring layer 13 and the third wiring layer 15 is formed, and an n-layer built-up wiring layer (n is an integer of 1 or more) may be formed.

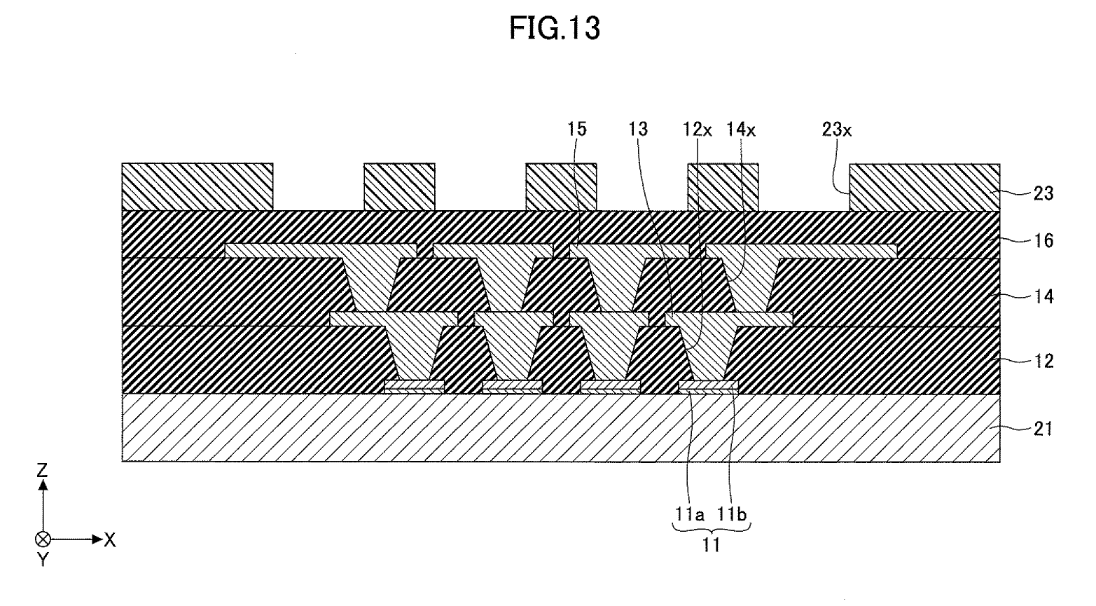

Referring to FIG. 13, the resist layer 23 having the opening portions 23x is formed on the third insulating layer 16. Specifically, a liquid-like or paste-like resist made of a photosensitive resin composition containing an epoxy resin, an imide resin or the like is coated on the third insulating layer 16. Alternatively, a film resist such as a dry film resist made of a photosensitive composition containing an epoxy resin, an imide resin or the like is laminated on the third insulating layer 16. By irradiating the coated or laminated resist with light and developing the coated or laminated resist, the opening portion 23x is formed. With this, the resist layer 23 having the opening portions 23x are formed. It is possible to laminate a film-like resist previously having the opening portions 23x on the third insulating layer 16.

The opening portions 23x are formed at positions corresponding to the opening portions 16x formed in a step to be illustrated in FIG. 14. However, a pitch of arranging the opening portions 23x may be about 500 through 1200 μm. The opening portion 23x is in a circular shape in its plan view, and a diameter of the opening portion 23x may be about 220 through 1100 μm.

The resist layer 23 functions as the mask of the blast process in the process illustrated in FIG. 14 described below. A part of the surface of the resist layer 23 may be removed by the blast process. The thickness of the resist layer 23 may be determined to enable functioning as a mask when a part of the surface of the resist layer 23 is removed by the blast process. The thickness of the resist layer 23 may be about 50 μm.

In the process illustrated in FIG. 14, the resist layer 23 is subjected to the blast process in the direction of the arrows. The opening portions 16x are formed in the third insulating layer 16 to cause portions of the upper surface of the third wiring layer 15 to be exposed to the outside. Further, the blast process is continued and the recesses 15x are formed at the exposed portions toward insides of the opening portions 16x of the third wiring layer 15. After causing the portions of the upper surface of the third wiring layer 15 to be exposed to the outside, the blast process is further continued to form the recesses 15x. Thus, it is possible to prevent the residue of the material of the third insulating layer 16 from remaining inside the opening portions 16x.

If pads having a diameter larger than the diameter of bottom portions of the opening portions 16x are formed on the third wiring layer 15 at the portions in which the opening portions 16x are formed, the pads receive an abrading agent when the opening portions 16x are formed by the blast process. Thus, the second insulating layer 14 is preferably prevented from being abraded by the blast process.

The opening portions 16x and the recesses 15x formed by the blast process have the shape illustrated in FIG. 4. With this, the third insulating layer 16 having the opening portions 16x is formed. The recesses 15x of the third wiring layer 15 exposed toward the inside of the opening portions 16x function as the electrode pads electrically connected to the mounting board (not illustrated) such as the motherboard.

The blast process is to mechanically adjust a surface roughness of a processed material by blowing an abrading agent to the processed material with a high pressure. The blast process includes an air blast process, a shot blast process, a wet blast process, or the like. It is preferable to use the wet blast process. The wet blast process is carried out by dispersing the abraded agent such as alumina abrasive grains and spherical silica abrasive grains to cause the abraded agent to crash into an object to be processed thereby abrading a minute region.

With the wet blast process, abrading can be very delicately carried out without causing damage in comparison with the air blast process and the shot blast process. Further, since the abrading agent is dispersed into the solution such as water, the abrading agent does not fly apart in the air as particles although the abrading agent flies apart in the air as particles in the air blast process and the shot blast process.

The grain diameter of the abrading agent such as the alumina abrasive grain or the spherical silica abrasive grain used for the wet blast process is about 5 through 20 μm. The concentration of the abrading agent such as the alumina abrasive grain or the spherical silica abrasive grain in a solvent such as water may be about 14 vol %. The injection pressure of injecting the solvent such as water in which the abrading agent is dispersed onto the surface of the processed material may be 0.25 MPa.

The surface roughness Ra of the sidewall of the opening portion 16x may be about 150 through 600 nm. The surface roughness Ra of the upper surface of the third insulating layer 16 other than the opening portion 16x may be about 150 nm or less. This is because the upper surface of the third insulating layer 16 is masked by the resist layer 23 to prevent the abrading agent from striking directly on the upper surface of the third insulating layer 16. As described, only the sidewall of the opening portion 16x is roughened and the upper surface of the third insulating layer 16 except for the opening portions 16x is not roughened. When the opening portions 16x are formed by the laser processing method, the sidewall of the opening portions 16x and the upper surface of the third insulating layer 16 are etched to have the surface roughness Ra of about 500 nm.

When necessary, a metallic layer or the like may be formed on the recesses 15x of the third wiring layer 15 which are exposed inside the opening portions 16x by electro plating. An example of the metallic layer is an Au layer, a Ni/Au layer which is a metallic layer formed by laminating a Ni layer and an Au layer in this order, a Ni/Pd/Au layer which is a metallic layer formed by laminating a Ni layer, a Pd layer, and an Au layer in this order or the like. However, the metallic layer or the like may be formed after removing the resist layer 23.

Like a case where the opening portions 16x are formed by the laser processing method and the desmear process, when the surface roughness of the upper surface of the third insulating layer 16 is large (Ra of about 500 nm), the metallic layer may be adhered to the upper surface of the third insulating layer 16 (anomalous deposition). When the opening portion is formed by the blast process, the desmear process can be omitted. Therefore, it is possible to decrease the surface roughness Ra of the upper surface of the third insulating layer 16 to be about 150 nm. Then, the above problem of the adhesion (anomalous deposition) is avoidable.

Further, since the surface roughness Ra of the sidewall of the opening portion 16x is so great as about 150 through 600 nm, when solder (e.g., solder ball, or solder bump) for electrically connecting to the third wiring layer 15 is formed inside the opening portion 16x, it is possible to enhance the contact between the sidewall of the opening portion 16x and the solder.

After the process illustrated in FIG. 14, the resist layer 23 illustrated in FIG. 14 is removed, and the supporting body 21 illustrated in FIG. 14 is further removed. Thus, the wiring substrate 10 illustrated in FIG. 3 and FIG. 4 is completed. The supporting body 21 made of the copper foil may be removed by wet etching using aqueous ferric chloride, aqueous copper chloride, aqueous ammonium persulfate or the like. At this time, the outermost layer lla of the first wiring layer 11 exposed from the first insulating layer 12 is a gold (Au) film. Therefore, only the supporting body 21 made of the copper foil can be selectively etched. When the third metallic layer 15 is made of copper (Cu), the third wiring layer 15 may be masked in order to prevent the third wiring layer 15 from being etched together with the supporting body 21.

Referring to FIG. 6 to FIG. 14, the wiring substrate 10 has been formed on the supporting body 21. However, it is also possible to form a member to have plural wiring substrates 10 on the supporting body 21 and acquire plural wiring substrates 10 by individually separating the wiring substrate 10 and the member. After removing the supporting body 21, it is possible to connect solder balls, lead pins or the like as external connection terminals to the recesses 15x.

According to Embodiment 1, it is possible to provide a wiring substrate with which connection reliability with a mounting board such as a motherboard and an electronic component such as a semiconductor chip can be improved and a manufacturing method of the wiring substrate. Said differently, since the opening portions of the uppermost insulating layer are formed by the blast process, the opening portions of the uppermost insulating layer are broadened from the side of the wiring layer to the open end (the upper surface of the insulating layer), and the cross-sectional shape of the sidewalls is concaved and curved. Therefore, if the areas of the upper surfaces of the wiring layer exposed inside the opening portions are the same, the areas of the opening portions having the sidewalls of the concaved and curved cross-sectional shape on the upper surface of the insulating layer 16 become greater than the areas of the opening portions having the sidewalls of the linear cross-sectional shape on the upper surface of the insulating layer 16. Said differently, accessible areas are different. Asa result, in comparison with the wiring substrate described in Japanese Laid-open Patent Publication No. 2000-286362 or No. 2008-140886, the pin for an LGA socket can be easily inserted and insertion failure and contact failure can be reduced.

Further, since the opening portions of the insulating layer are formed by the blast process, the desmear process can be omitted and the hollowing does not occur. As a result, it is possible to prevent the wiring layer 15 in the vicinity of the opening portions 16x and the insulating layer 16 covering the wiring layer 15 from causing the contact failure.

Meanwhile, the recesses 15x are formed by the blast process on the portions of the uppermost wiring layer 15 exposed inside the opening portions 16x of the uppermost insulating layer 16, and the bottom surfaces of the recesses 15x are positioned one step down from the interface between the wiring layer 15 in the vicinity of the opening portions and the insulating layer 16 covering the wiring layer 15. Therefore, a direct force is hardly applied to the interface between the wiring layer 15 and the insulating layer 16 covering the wiring layer 15 to thereby prevent the interface from peeling away.

Meanwhile, the nonphotosensitive insulating resin having the same composition as the material of the insulating layers 12, 14 and 16 may be used. Further, when the insulating layers contain the fillers having the same composition of substantially the same amount, it is possible to adjust the thermal expansion coefficients of the insulating layers to be substantially the same value. Thus, it is possible to prevent the wiring substrate from deflecting. Further, by bringing the thermal expansion coefficients of the insulating layers 12, 14 and 16 closer to the thermal expansion coefficient of the wiring layer 11, 13 or 15, it is possible to further reduce the warpage of the wiring substrate.

In case of using the photosensitive insulating resin for the uppermost insulating layer, such an effect is not obtainable. When the amount of the filler contained in the photosensitive insulating resin is increased, exposure may not be performed. Therefore, there is a limit to the amount of the filler which may be contained in the photosensitive insulating resin. It is difficult to freely adjust the contained amount to the filler in order to obtain a desirable thermal expansion coefficient and bring the thermal expansion coefficient to about 60 ppm/° C. or less. Therefore, the thermal expansion coefficients of the insulating layers 12, 14 and 16 cannot be brought closer to the wiring layer thermal expansion coefficient (e.g., the thermal expansion coefficient of copper (Cu) of about 17 ppm/° C.). On the other hand, nonphotosensitive insulating resins have a degree of freedom in adjusting the filler amount in comparison with photosensitive insulating resins. The thermal expansion coefficients of the nonphotosensitive insulating resins can be adjusted in a range of about 20 through 70 ppm/° C. Therefore, the thermal expansion coefficients of the insulating layers can be brought closer to the thermal expansion coefficient of the wiring layer (e.g., the thermal expansion coefficient of copper (Cu) of about 17 ppm/° C.).

Further, only the sidewall of the opening portion can be roughened by the blast process using a predetermined mask. When solder, a solder ball, a solder bump or the like is formed inside the opening portion, it is possible to improve contact between the sidewall and the solder of the opening portion by an anchor effect. Further, because the uppermost insulating layer covered by the mask in the blast process is not roughened, it is possible to prevent the metallic layer from adhering to the upper surface of the uppermost insulating layer other than the opening portion when the metallic layer or the like is formed by nonelectro plating on the wiring layer exposed inside the opening portion of the uppermost insulating layer.

### Modified Example of Embodiment 1

With Embodiment 1, the recesses in the uppermost insulating layer 16 exposed inside the opening portion functions as the electrode pads to be electrically connected to the mounting board such as the motherboard, and the lowermost wiring layer 11 functions as the electrode pads which are exposed from the lowermost insulating layer 12 and are electrically connected to the semiconductor chip.

With Modified example 1 of Embodiment 1, the recesses in the uppermost insulating layer 16 exposed inside the opening portions 16y function as the electrode pads to be electrically connected to a semiconductor chip or the like, and the lowermost wiring layer 11 functions as the electrode pads which are exposed from the lowermost insulating layer 12 and are electrically connected to the mounting board such as the motherboard. Said differently, a pitch of the recesses in the uppermost wiring layer exposed toward the opening portions of the uppermost insulating layer is narrowed more than the parts of the lowermost wiring layer 11 exposed from the lowermost insulating layer 12 in Modified example 1. Hereinafter, descriptions of the same parts as those described in Embodiment 1 are omitted, and different portions are mainly described.

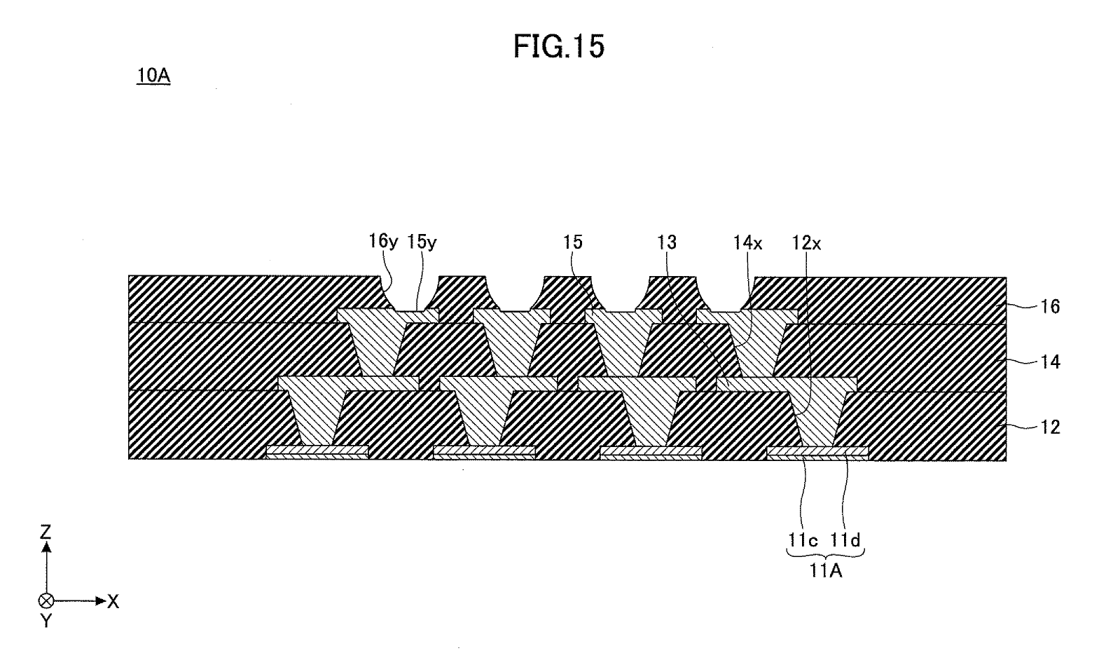

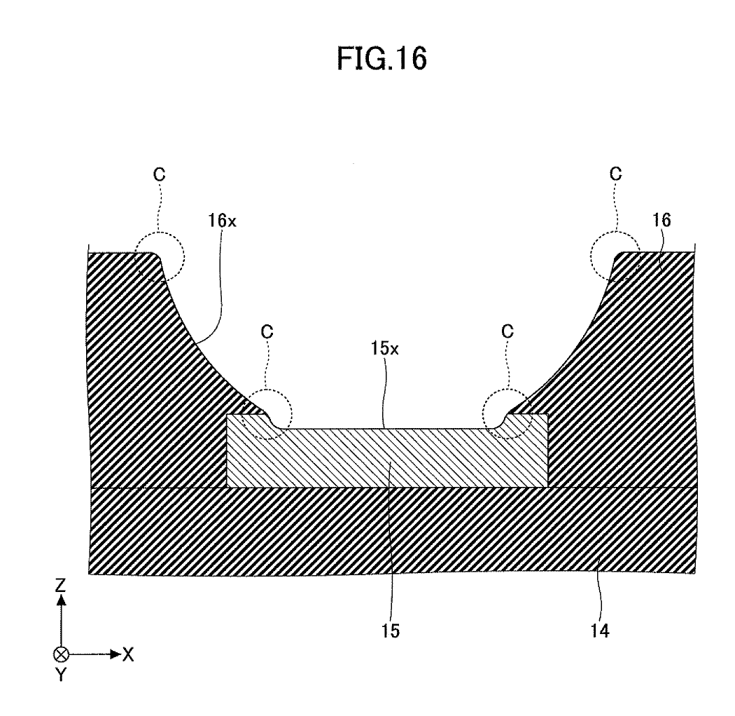

FIG. 15 is a cross-sectional view of an example wiring substrate of Modified example 1 of Embodiment 1. Referring to FIG. 15, the wiring substrate 10A of Modified example 1 of Embodiment 1 differs from the wiring substrate 10 (see FIG. 3) in that the first wiring layer 11 is replaced by a first wiring layer 11A, the recesses 15x are replaced by recesses 15y, and the opening portions 16x are replaced by opening portion 16y.

In the wiring substrate 10A, the first wiring layer 11A is positioned in the lower most layer of the wiring substrate 10A. The first wiring layer 11A includes a first layer 11c and a second layer 11d. The first layer tic maybe a conductive layer formed by sequentially laminating a gold (Au) film, a palladium (Pd) film and a nickel (Ni) film in this order while the gold (Au) layer is exposed to the outside of the wiring substrate 10A. The second layer 11d is a conductive layer including copper (Cu) or the like.

The first layer 11c being a part of the first wiring layer 11A has parts exposed from the first insulating layer 12 that function as electrode pads connected to a mounting board (not illustrated) such as a motherboard. A plan view of the parts of the layer 11c of the first wiring layer 11A exposed from the first insulating layer 12 may be in a circular shape, and the diameter of the circular shape may be about 200 through 1000 μm. The pitch of the layer 11c of the first wiring layer 11A exposing from the first insulating layer 11 may be about 500 through 1200 μm. The thickness of the first wiring layer 11A may be about 10 to 20 μm.

The third insulating layer 16 includes the opening portions 16y. The opening portion 16y is broadened toward an opening end of the opening portion 16y, and a cross-sectional view of a sidewall is in concaved and curved shape. The opening portion 16y is in a circular shape in its plan view, and a diameter of the opening portion 16y may be about 50 through 130 μm. The opening portion 16y may be formed like a hemisphere.

The recesses 15y of the third wiring layer 15 are exposed inside the respective opening portions 16y. The recess 15y is broadened from the bottom surface toward the opening end of the recess 15y, and a cross-sectional view of a sidewall is in a concaved and curved shape. The outer edge portion of the recess 15y does not intrude into a lower portion of the third insulating layer 16. The outermost edge portion of the sidewall of the recess 15y is continuously formed from the innermost edge portion of the sidewall of the opening portion 16y. Said differently, the outermost edge portion of the sidewall of the recess 15y is continuously curved from the innermost edge portion of the sidewall of the opening portion 16x in their cross-sectional shapes. The plan view of the recess 15y may be like a circle having a diameter of about 40 through 120 μm. The pitch of the recesses 15y may be about 100 through 200 μm. The depth of the recess 15y based on the upper surface of the third wiring layer 15 may be about 0.5 through 4 μm.

The recess 15y functions as an electrode pad connected to a semiconductor chip (not illustrated) or the like. When necessary, ametallic layer or the like may be formed on the recesses 15y. An example of the metallic layer is an Au layer, a Ni/Au layer which is a metallic layer formed by laminating a Ni layer and an Au layer in this order, a Ni/Pd/Au layer which is a metallic layer formed by laminating a Ni layer, a Pd layer, and an Au layer in this order or the like.

It is possible to form an external connection terminal such as a solder ball and a solder bump on the recess 15y. When a metallic layer or the like is formed on the recess 15y, it is possible to further form an external connection terminal such as a solder ball and a solder bump on the metallic layer. However, the external connection terminal may be formed when necessary.

The opening portions 16y and the recesses 15y may be formed by the blast process in a similar manner to the opening portions 16x and the recesses 15x. Because the manufacturing process of the wiring substrate 10A is similar to the manufacturing process of the wiring substrate 10, description of the manufacturing process is omitted.

With Modified example 1 of Embodiment 1, effects similar to those in Embodiment 1 are obtainable. Further, the following effects are obtainable. By narrowing the pitch of the recesses 15y exposed inside the opening portions 16y of the uppermost insulating layer 16 in comparison with the pitch of the portions of the first wiring layer 11 exposed from the first insulating layer 12, a semiconductor chip or the like may be mounted on a side of the recesses 15y.

### Modified Example 2 of Embodiment 1

With Embodiment 1, the opening portions 16x are formed by the blast process. With Modified example 2 of Embodiment 1, after the opening portion 16x is formed by the blast process (i.e., a first blast process), a second blast process is provided in the vicinity of the opening portions 16x. Hereinafter, descriptions of the same parts as those in Embodiment 1 are omitted, and different portions are mainly described.

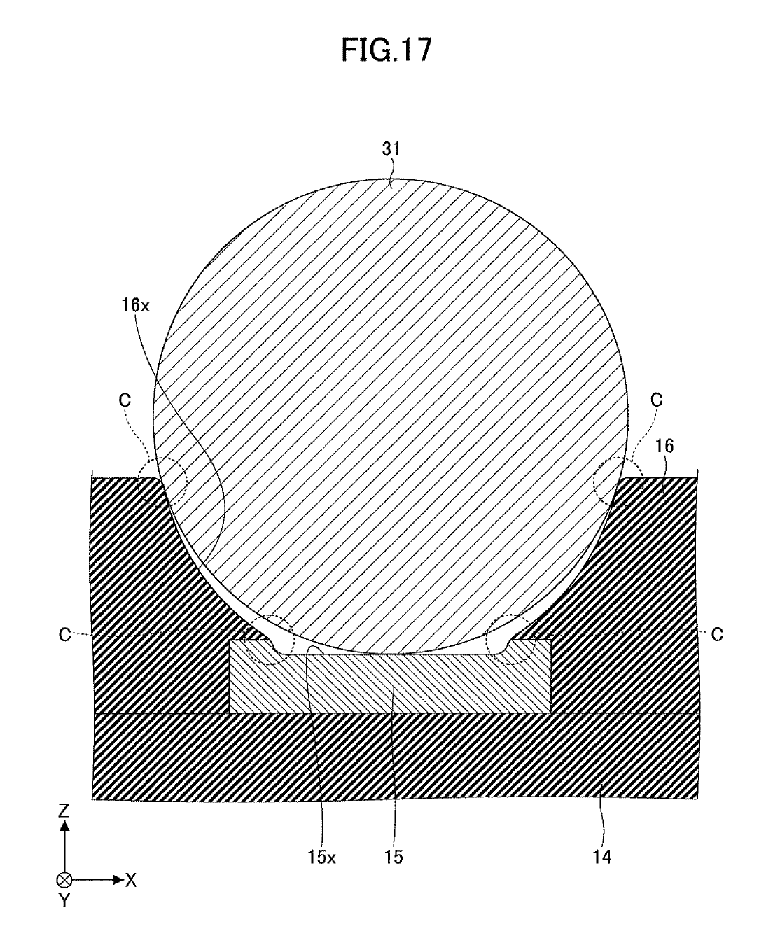

FIG. 16 is an enlarged cross-sectional view of the opening portion 16x and portions in the vicinity of the opening portion 16x of a wiring substrate of Modified example 2 of Embodiment 1. Referring to FIG. 16, the cross-sectional view of corners C of the opening portion 16x and the recess 15x of the wiring substrate of Modified example 2 is in a projected and curved shape. This projected and curved shape is formed by removing the resist layer 23 and providing the second blast process after the first blast process illustrated in FIG. 14.

The second blast process is provided to abrade a slight amount for a very short time. Therefore, if the second blast process is carried out without providing a resist layer as a mask, it is possible to maintain a surface roughness Ra of the upper surface of the third insulating layer 16 except for the opening portions 16x to be 150 nm or less. However, it is possible to provide a resist layer having opening portions larger than the opening portions 16x on the third insulating layer 16 and carry out the blast process via the resist layer so that the corners C are exposed from the opening portion of the resist layer to shape the corners C to be in the projected and curved shape.

FIG. 17 is a cross-sectional view of the opening portion of the wiring substrate and the portions in the vicinity of the opening portion of Modified example 2 of Embodiment 1. Referring to FIG. 17, since, in the cross-sectional view, the corners C of the opening portion 16x are in the projected and curved shape, it is possible to stably arrange the conductive ball 31 such as a solder ball even by roughly positioning the conductive ball 31. This stable arrangement may also be achieved when a lead pin or the like is roughly positioned instead of the conductive ball 31.

With Modified example 1 of Embodiment 2, effects similar to those in Embodiment 1 are obtainable. Further, the following effects are obtainable. By forming, in the cross-sectional view, the corner of the opening portion to be the projected and curved shape, it is possible to easily arrange the connection terminals such as the conductive ball and the lead pin.

### Modified Example 3 of Embodiment 1

With Embodiment 1, the opening portion 16x having a substantially circular shape in its plan view is formed in the uppermost insulating layer 16 by the blast process. With Modified example 3 of Embodiment 1, an opening portion 16z having a substantially rectangular shape in its plan view is formed by a blast process. Hereinafter, descriptions of the same parts as those in Embodiment 1 are omitted, and different portions are mainly described.

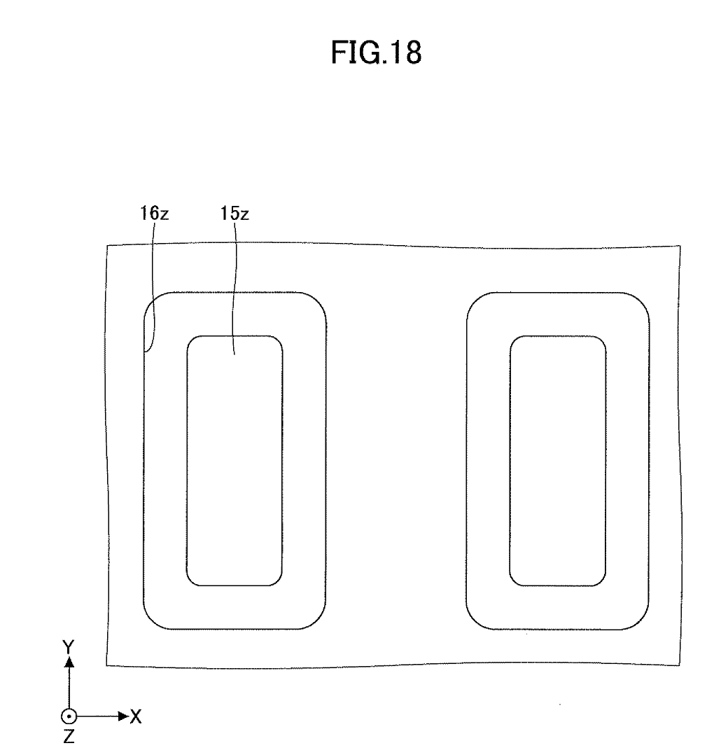

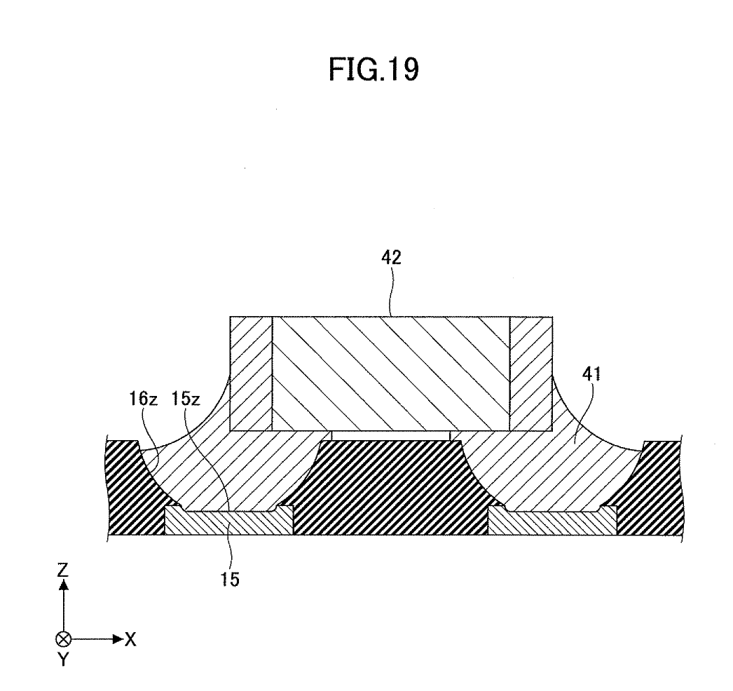

FIG. 18 is an enlarged plan view of the opening portion 16z in a wiring substrate and portions in the vicinity of the opening portion 16z of Modified example 3 of Embodiment 1. FIG. 19 is a cross-sectional view of the wiring substrate having a chip capacitor mounted in the wiring substrate of Modified example 3 of Embodiment 1. Referring to FIG. 18 and FIG. 19, a cross-sectional shape of the opening portion 16z is broadened from the third wiring layer 15 toward an opening end, and the cross-sectional shape of the sidewall is in a concaved and curved. The opening portion is formed to be broadened from the outermost wiring layer to an upper surface of the outermost insulating layer. The plan view of the opening portion 16z may substantially be a rectangle having curved corners. The size of the opening portion 16z may be 650 μm (X direction) and 1400 μm (Y direction).

In plan view, the recess 15z of the opening portion 16z may substantially be a rectangle having curved corners. The size of the recess 15z may be 550 μm (X direction) and 1300 μm (Y direction). A pitch of adjacent recesses 15z may be appropriately determined in conformity with a pitch of mounted parts. The depth of the recess 15z based on the upper surface of the third wiring layer 15 may be about 0.5 through 4 μm.

A capacitor 42 is mounted via solder 41 in adjacent recesses 15z. However, the mounted parts are not limited to the capacitor and various electronic parts such as a resistor, an inductor and a transistor can be mounted. The sizes and pitches of the opening portion 16z and the recesses 15z can be properly determined in conformity with the sizes and pitches of the mounted electronic parts.

By using the blast process, the large opening portions 16z can be formed within an extremely short time. Meanwhile, when the large opening portions 16z are formed by a laser process, several shots of irradiations are provided to thereby increase a processing time.

Because the opening portion 16z having the substantially rectangular shape in its plan view is for various electronic parts, the opening portions 16z may be provided beside the opening portion 16x having the substantially circular shape in its plan view. Said differently, both of the opening portion 16x and the opening portion 16z may exist on the same wiring substrate. However, the electrode pad and the opening portion of the electrode pad may be substantially shaped like a rectangle. For example, depending on the shape of a pin of a socket to be inserted into the opening portion, it is possible to obtain an effect that workability in inserting the pin is improved by providing a substantially rectangular electrode pad, forming a substantially rectangular opening portion for the electrode pad, and inserting the pin into the opening portion while arranging a longitudinal direction of the opening portion in a longitudinal direction of the pin.

With Modified example 3 of Embodiment 1, effects similar to those in Embodiment 1 are obtainable. Further, the following effects are obtainable. By using the blast process, not only the opening portion 16x having the substantially circular shape in its plan view but also the opening portion 16z having the substantially rectangular shape in its plan view are formed in a relatively short processing time in comparison with a laser processing method. As a result, it is possible to easily form a relatively large opening portion for mounting various electronic parts such as a capacitor.

### Embodiment 2

With the example of Embodiment 1, the uppermost insulating layer is made of the nonphotosensitive insulating resin. With an example of Embodiment 2, an uppermost insulating layer is made of a material formed by impregnating glass cloth with a nonphotosensitive insulating resin. Hereinafter, descriptions of the same parts as those in Embodiment 1 are omitted, and different portions are mainly described.

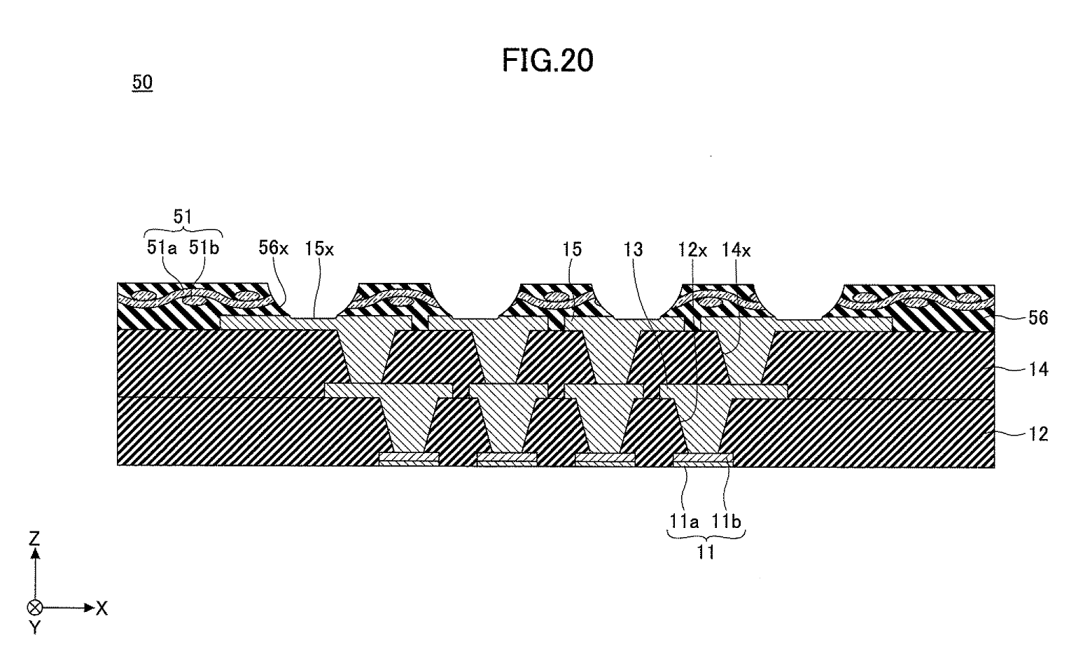

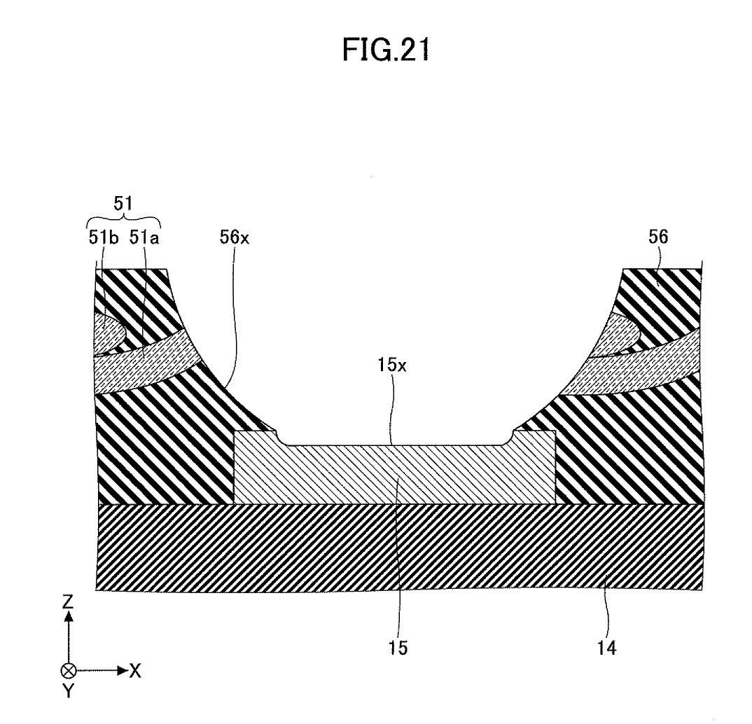

FIG. 20 is a cross-sectional view of an example wiring substrate of Embodiment 2. FIG. 21 is an enlarged cross-sectional view illustrating an opening portion 56x of FIG. 20 and portions in the vicinity of the opening portion. Referring to FIG. 20 and FIG. 21, a wiring substrate 50 of Embodiment 2 is formed by replacing the third insulating layer 16 of the wiring substrate 10 illustrated in FIG. 3 in Embodiment 1 by a third insulating layer 56.

The third insulating layer 56 may be formed by impregnating glass cloth with a nonphotosensitive insulating resin in which an epoxy resin is a main component. The material of the third insulating layer 56 is a nonphotosensitive insulating resin having the same composition as the first insulating layer 12 and the second insulating layer 14. The third insulating layer 56 preferably contains a filler having the same composition as the filler contained in the first insulating layer 12 and the second insulating layer 14 of substantially the same amount as that of the filler. This is to reduce warpage caused in the wiring substrate 50. The thickness of the third insulating layer 56 may be about 25 through 75 μm.

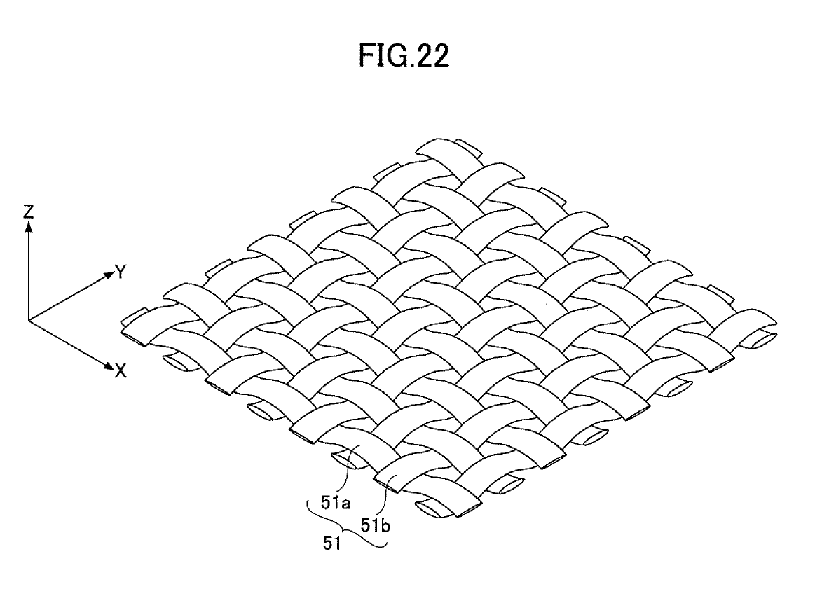

Referring to FIG. 22, the glass cloth 51 is formed by flatly weaving glass fiber bundles arranged in an X direction in parallel with one another and glass fiber bundles arranged in a Y direction in parallel one another. The glass cloth 51 is a grid-like mesh. The glass cloth 51 is a representative example of a reinforcing member formed by weaving the glass fiber bundles of the grid-like mesh. Each of the glass fiber bundles 51a and 51b is formed by binding up glass fibers having a width of about several μm so as to have a width of about several 100 μm. The thicknesses of the glass fiber bundles 51a and 51b are about 10 through 15 μm.

The reinforcing member is not limited to the above glass fiber bundles (fascicles) and may be fiber bundles such as carbon fiber bundles, polyester fiber bundles, tetronic fiber bundles, nylon fiber bundles, aramid fiber bundles or the like. The fiber bundles may not be the flat weave and may be satin weave, twill weave or the like. It is possible to use nonwoven fabric except for the finished fabric.

As a material of the insulating layers forming the wiring substrate 50, a nonphotosensitive insulating resin having a uniform composition may be used. When all the insulating layers contain fillers having the identical composition of substantially the identical amount, it is possible to reduce warpage caused in the wiring layer 50. However, the wiring layer ordinarily used as the electrode pad (the third wiring layer 15 in Embodiment 2) has a lower copper area rate (e.g., a rate of occupying area relative to an entire copper foil region) than those of the other wiring layers. The wiring substrate is apt to deflect because of the difference of the copper area rates. Therefore, by providing the glass cloth 51 inside the third insulating layer 56 adjacent to the third wiring layer 15, it is possible to obtain an effect similar to a case where the copper area rate of the third wiring layer 15 is increased thereby further reducing the warpage caused in the wiring substrate.

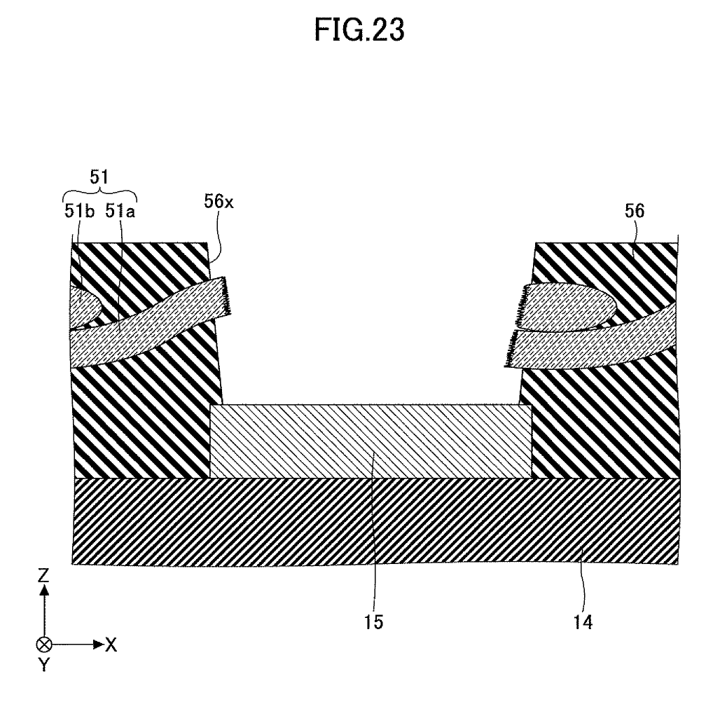

Meanwhile, referring to FIG. 23, when an opening portion 56x is formed by a laser processing method in the third insulating layer 56 in which the glass cloth 51 is provided, an edge portion of the glass cloth 51 protrudes from a sidewall of the opening portion 56x. When the edge portion of the glass cloth 51 protrudes from the sidewall of the opening portion 56x and a metallic layer such as an Au layer is formed on the third wiring layer 15 by a nonelectro plating method, there is caused a problem that a thickness of plating film on the third wiring layer 15 becomes small. Further, there may be caused problems such that a connection pin is difficult to be inserted or is not inserted. Further, there may be caused problems such that a solder ball, a lead pin or the like as the external connection terminal is difficult to be arranged in the opening portion 56x.

Meanwhile, referring to FIG. 21 of Embodiment 2, the edge portion of the glass cloth 51 is abraded by an abrading agent and does not protrude from the sidewall of the opening portion 56x. As a result, the above-mentioned problem does not occur.

With Embodiment 2, effects similar to those in Embodiment 1 are obtainable. Further, the following effects are obtainable. By using the insulating resin with which the glass cloth is impregnated, it is possible to bring the thermal expansion coefficient of the uppermost insulating layer to that of copper. Therefore, it is possible to further reduce the warpage of the wiring substrate. It is possible to make the strength of the wiring substrate high using the reinforcing member such as the glass cloth.

By the blast process, the end portion of the glass cloth does not protrude from the side wall. Therefore, it is easy to provide plating on the wiring layer exposed inside the opening portion and arrange a connection pin, a connection solder ball, a connection lead pin or the like inside the opening portion.

It is possible to modify Embodiment 2 in a similar manner to Modified examples 1 through 3 of Embodiment 1.

### Embodiment 3

With Embodiment 3, an example of the semiconductor package in which the semiconductor chip is mounted in the wiring substrate 10 illustrated in FIG. 3 of Embodiment 1 is described. Hereinafter, descriptions of the same parts as those in Embodiment 1 are omitted, and different portions are mainly described.

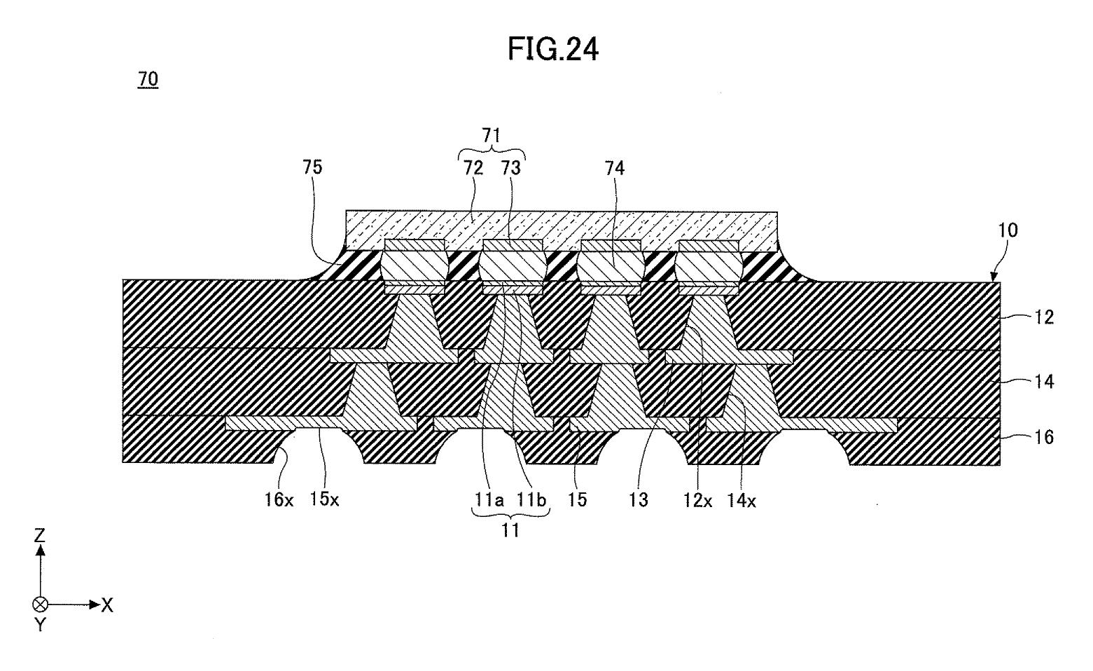

FIG. 24 is a cross-sectional view of a semiconductor package of Embodiment 3. Referring to FIG. 24, a semiconductor package 70 includes the wiring substrate 10 illustrated in FIG. 3, a semiconductor chip 71, solder bumps 74, and an underfill resin 75 . FIG. 24 is a cross-sectional view of the wiring substrate 10 illustrated by turning the wiring substrate 10 illustrated in FIG. 3 upside down.

The semicondutor chip 71 includes a main body 72 and electrode pads 73. The main body 72 is formed by providing a semiconductor integrated circuit (not illustrated) on a semiconductor substrate (not illustrated) which is thinned and made of silicon or the like. The electrode pads 73 are formed on the main body 72. The electrode pads 73 are electrically connected to the semiconductor integrated circuit (not illustrated). The material of the electrode pads 73 may be Au or the like.

The bumps 74 electrically connect the electrode pads 73 of the semiconductor chip 71 to the first layer 11a of the first wiring layer 11 exposed from the first insulating layer 12 of the wiring substrate 10. The bumps 74 may be solder bumps. The material of the solder bumps may be an alloy containing Pb, an alloy containing Sn and Cu, an alloy containing Sn and Ag, an alloy containing Sn, Ag, and Cu, or the like. The underfill resin 75 is supplied between a surface of the wiring substrate 10 and the semiconductor chip 71.

As described, the semiconductor package in which the semiconductor chip is mounted on the wiring substrate of Embodiment 1 can be realized.

### Embodiment 4

With Embodiment 4, an example of the semiconductor package in which the semiconductor chip is mounted in the wiring substrate 10A illustrated in FIG. 15 of Modified example 1 of Embodiment 1 is described. Hereinafter, descriptions of the same parts as those in Embodiment 1 are omitted, and different portions are mainly described.

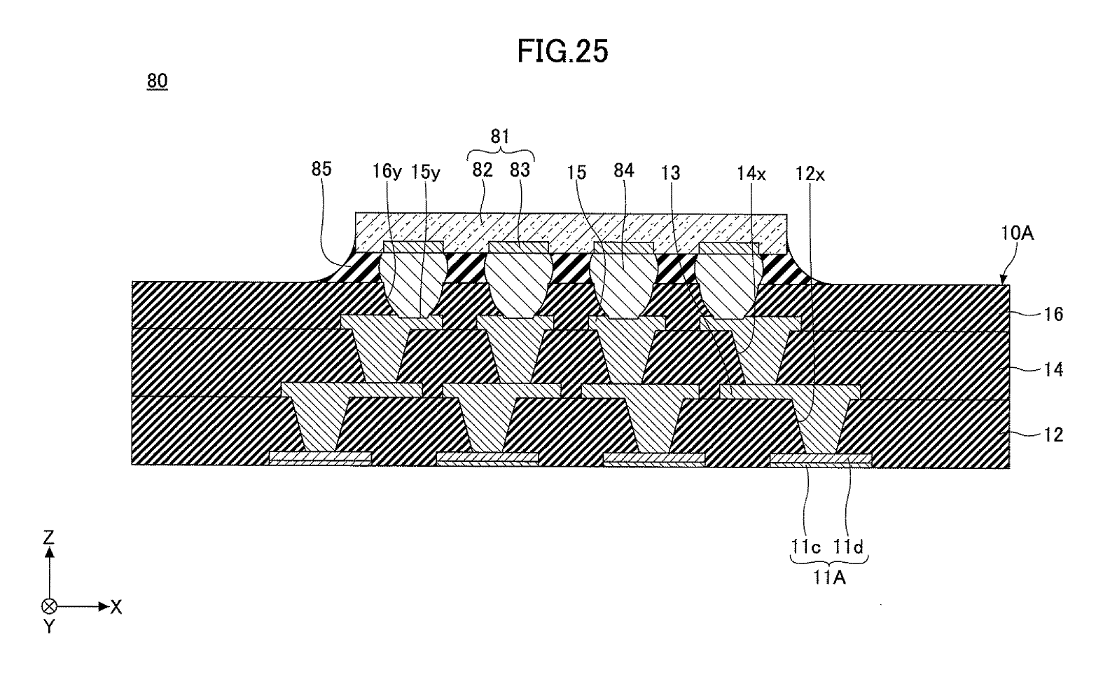

FIG. 25 is a cross-sectional view of a semiconductor package of Embodiment 4. Referring to FIG. 25, a semiconductor package 80 includes the wiring substrate 10A illustrated in FIG. 15, a semiconductor chip 81, bumps 84, and an underfill resin 85.

The semiconductor chip 81 includes a main body 82 and electrode pads 83. The main body 82 is formed by providing a semiconductor integrated circuit (not illustrated) on a semiconductor substrate (not illustrated) which is thinned and made of silicon or the like. The electrode pads 83 are formed on the main body 82. The electrode pads 83 are electrically connected to the semiconductor integrated circuit (not illustrated). The material of the electrode pads 83 may be Au or the like.

The bumps 84 electrically connect the electrode pads 83 of the semiconductor chip 81 to the recesses 15y of the third wiring layer 15 exposing from the opening portions 16y of the third insulating layer 16 of the wiring substrate 10A. The bumps 84 may be solder bumps. The material of the solder bumps may be an alloy containing Pb, an alloy containing Sn and Cu, an alloy containing Sn and Ag, an alloy containing Sn, Ag, and Cu, or the like. The underfill resin 85 is supplied between a surface of the wiring substrate 10A and the semiconductor chip 81.

As described, the semiconductor package in which the semiconductor chip is mounted on the wiring substrate of Modified example 1 of Embodiment 1 can be realized.

### Comparative Example 1

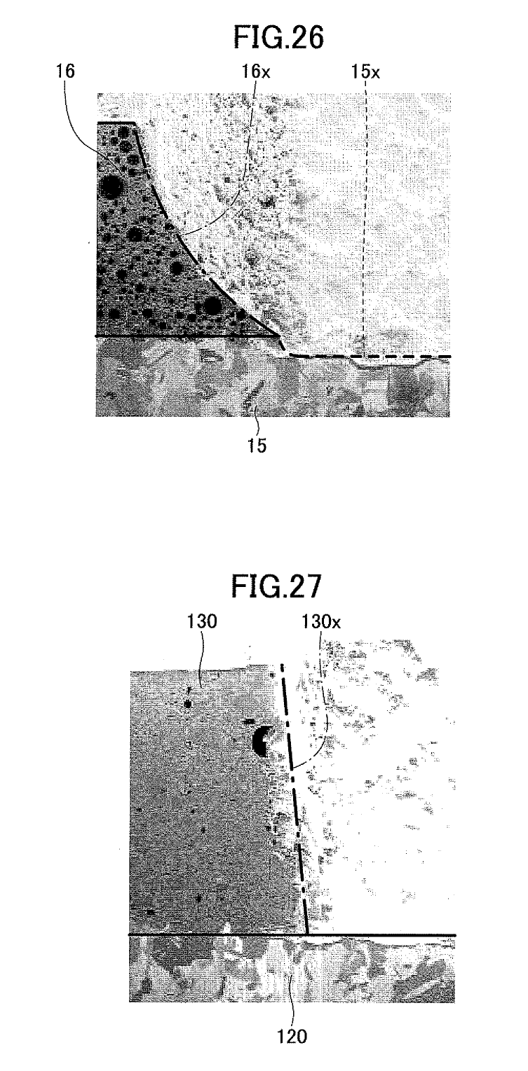

FIG. 26 is an electron microscope photograph of the opening portion of the wiring substrate and portions in the vicinity of the opening portion of Embodiment 1 captured by a scanning electron microscope (SEM). The wiring substrate of Embodiment 1 is manufactured by a method illustrated in FIG. 6 through FIG. 14. The third wiring layer 15 is made of copper (Cu). The third insulating layer 16 is formed by a nonphotosensitive epoxy resin. The opening portion 16x and the recess 15x are formed by a wet blast process in which the particle diameter of an abrading agent is about 5 through 20 μm, the concentration of the abrading agent is about 14 vol %, and an injection pressure of about 0.25 MPa.

Referring to FIG. 26, the opening portion 16 formed by the wet blast process is broadened toward an opening end of the opening portion 16x, and the cross-sectional view of a sidewall is in a concaved and curved shape as indicated by a dashed-dotted line. Further, it is possible to confirm that the recess 15x is formed inside the opening portion 16x as indicated by a dashed line. The upper surface of the third wiring layer 15 is indicated by a solid line.

FIG. 27 is an electron microscope photograph of an opening portion of a wiring substrate and portions in the vicinity of the opening portion of Comparative Example 1 captured by a scanning electron microscope (SEM). A wiring layer 120 of the wiring substrate of Comparative Example 1 is made of copper (Cu). Further, a second insulating layer 130 is formed of a photosensitive epoxy resin, and an opening portion 130x is formed by a photolithographic method. Referring to FIG. 27, a cross-sectional view of a sidewall of the opening portion 130x is in a linear shape indicated by a dashed-dotted line and a recess is not formed inside the opening portion 130x. The upper surface of a wiring layer 120 is indicated by a solid line.

As described, the opening portion formed by the blast process is different from the opening portion formed by the photolithographic method. It is confirmed that the cross-sectional view of the sidewall of the opening portion formed by the blast process is in the concaved and curved shape, and the uppermost wiring layer exposed inside the opening portion has the recess.

In the above Examples and Modified examples, the “uppermost wiring layer” may also be referred to as an outermost wiring layer, and the “lowermost insulating layer” may also be referred to as an innermost insulating layer. Said differently, the opening portions of the Embodiments and the Modified examples are formed on the outermost insulating layer covering one of the outermost insulating layers of the wiring substrate.

With the Embodiments and the Modified examples, the coreless wiring substrate may be manufactured by a build-up manufacturing method. However, the present invention is not limited to this and is applicable to various wiring substrates. Specifically, the present invention may be applicable to a wiring substrate which has a core and manufactured by the build-up manufacturing process, a through-type multilayer wiring substrate in which wiring layers are connected by a through via, or an IVH multilayer wiring substrate in which a specific wiring layer is connected by an interstitial via hole (IVH).

With the Embodiments and the Modified examples, the wiring layer and the insulating layer are laminated on a surface (side) of the supporting body by the build-up manufacturing process, and the supporting body is removed to manufacture the coreless wiring substrate. However, it is possible to laminate wiring layers and insulating layers on both surfaces of the supporting body by the build-up manufacturing method, and the supporting body is finally removed to thereby manufacture the coreless wiring substrate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A wiring substrate comprising:
a plurality of insulating layers; and
a plurality of wiring layers being alternately laminated,
wherein an opening portion is formed in an outermost insulating layer to expose a part of the outermost wiring layer to an outside,
a cross-sectional shape of a sidewall of the opening portion is concaved and curved, and
the outermost wiring layer has a recess on a side exposed to the outside.

2. The wiring substrate according to claim 1,
wherein an outermost edge portion of a sidewall of the recess is continuously curved from an innermost edge portion of the sidewall of the opening portion in their cross-sectional shapes.

3. The wiring substrate according to claim 1,
wherein the plurality of laminated insulating layers are made of insulating resins having identical compositions and contain fillers having identical compositions.

4. The wiring substrate according to claim 1,
wherein a surface roughness of the sidewall of the opening portion is greater than a surface roughness of an upper surface of the outermost insulating layer.

5. The wiring substrate according to claim 1,
wherein the outermost insulating layer includes a reinforcing member in addition to an insulating resin.

6. The wiring substrate according to claim 1,
wherein the opening portion is broadened from the outermost wiring layer to an upper surface of the outermost insulating layer.

7. A manufacturing method of a wiring substrate comprising:
laminating a plurality of insulating layers and a plurality of wiring layers alternately,
forming, by a first blast process, an opening portion in an outermost insulating layer to expose a part of the outermost wiring layer to an outside,
forming, by a second blast process, a recess in the outermost wiring layer on a side exposed by the opening portion to the outside .

8. The manufacturing method of the wiring substrate according to claim 7,
wherein, in the laminating, the plurality of the wiring layers and the plurality of insulating layers are alternately laminated on a supporting body,
after the forming of the recess by the second blast process, the supporting body is removed.

9. The manufacturing method of the wiring substrate according to claim 7, further comprising:
arranging a mask exposing apart in which the opening potion is formed on an upper surface of the outermost insulating layer before the first blast process,
wherein the first blast process is performed on the upper surface of the outermost insulating layer via the mask to form the opening portion.

10. The manufacturing method of the wiring substrate according to claim 7, further comprising:
performing a third blast process, after the forming of the recess by the second blast process on the opening portion to form corners of the opening portion and the recess to have projected and curved shapes.

11. The manufacturing method of the wiring substrate according to claim 7,
wherein the outermost insulating layer includes a reinforcing member in addition to an insulating resin, and
the forming of the opening portion by the first blast process is provided to prevent an end portion of the reinforcing member from protruding inside the opening portion.

12. The manufacturing method of the wiring substrate according to claim 7,
wherein one of the first blast process, the second blast process or the first and second blast processes is a wet blast process.

13. The manufacturing method of the wiring substrate according to claim 7,
wherein a cross-sectional shape of a sidewall of the opening portion is formed to be concaved and curved.

14. The manufacturing method of the wiring substrate according to claim 7,
wherein the opening portion is formed to be broadened from the outermost wiring layer to an upper surface of the outermost insulating layer.
